(19) United States
(12) Patent Application Publication
(10) Pub. No.: US 2020/0295063 A1
(43) Pub. Date: Sep. 17, 2020

(54) PHOTOELECTRIC CONVERSION APPARATUS, MANUFACTURING METHOD THEREOF, EQUIPMENT, AND MOVING BODY

(71) Applicant: CANON KABUSHIKI KAISHA, Tokyo (JP)

(72) Inventors: Yoshiyuki Nakagawa, Yokohama-shi (JP); Takafumi Miki, Yokohama-shi (JP); Akira Ohtani, Ebina-shi (JP); Masashi Kusukawa, Kawasaki-shi (JP)

(21) Appl. No.: 16/811,845

(22) Filed: Mar. 6, 2020

(30) Foreign Application Priority Data
Mar. 14, 2019 (JP) 2019-047077
Mar. 29, 2019 (JP) 2019-068300

(51) Int. Cl. H01L 27/146; H04N 5/359

(52) U.S. Cl. CPC H01L 27/14607; H01L 27/14643; H01L 27/14614; H01L 27/1462; H04N 5/359; H01L 27/1464; H01L 27/14685; H01L 27/14689; H01L 27/14636

(57) ABSTRACT

A photoelectric conversion apparatus includes: a substrate having a photoelectric conversion portion; a gate electrode of a transfer transistor provided on the substrate and configured to transfer charges generated by the photoelectric conversion portion; a first film; a second film provided on the first film; and a contact plug being in contact with the second film and connected to the transfer transistor.

### BACKGROUND OF THE INVENTION

### Field of the Invention

The present invention relates to a photoelectric conversion apparatus.

### Description of the Related Art

Photoelectric conversion apparatuses are widely used as imaging apparatuses in two-dimensional image-input apparatus such as a digital still camera, a video camcorder, or the like, for example. Due to a demand for improving performance of two-dimensional image-input apparatuses, there is also a demand for improvement of image quality in imaging apparatuses, and study for increasing a signal/noise (S/N) ratio of an output signal has been made. One scheme for increasing the S/N ratio of the imaging apparatus may be a method of reducing a parasitic capacitance of a floating diffusion portion to increase photoelectric conversion efficiency and reducing random noise superimposed on an output signal. Herein, the parasitic capacitance of a floating diffusion portion may be a p-n junction capacitance in a diffusion layer, an interlayer capacitance between the floating diffusion portion and a wiring connected to a floating diffusion portion, a capacitance between the floating diffusion portion and a transfer gate electrode, or the like.

Japanese Patent Application Laid-Open No. 2008-041726 discloses a technology for reducing noise due to hot carriers occurring at p-n junction between a channel region and a drain region of a transfer transistor.

Japanese Patent Application Laid-Open No. 2007-165864 discloses a photoelectric conversion apparatus in which an anti-reflection film is arranged above a light receiving face of a photoelectric conversion element, an element isolation region having an insulating member, and an active region in which a contact is formed. Further, Japanese Patent Application Laid-Open No. 2007-165864 discloses that the anti-reflection film serves as an etching stop film used in etching when the contact is formed.

### SUMMARY OF THE INVENTION

According to one aspect of the present invention, provided is a photoelectric conversion apparatus including: a substrate having a photoelectric conversion portion and a floating diffusion portion; a gate electrode of a transfer transistor provided on the substrate and configured to transfer charges generated by the photoelectric conversion portion to the floating diffusion portion; a first film formed of an insulating material whose relative dielectric constant is lower than 5.0 and provided so as to cover at least a side face of the gate electrode of the transfer transistor, the side face being on the floating diffusion portion side; a second film provided on the first film; and a contact plug being in contact with the second film and connected to the transfer transistor, wherein in a range which is above the floating diffusion portion and in which a distance from an intersection line of a face including the side face of the gate electrode and a surface of the substrate is less than or equal to a distance corresponding to a height of the gate electrode from the surface, the photoelectric conversion apparatus includes no insulating material whose relative dielectric constant is higher than or equal to 5.0.

According to another aspect of the present invention, provided is a photoelectric conversion apparatus including: a substrate having a photoelectric conversion portion; a gate electrode of a transfer transistor provided on the substrate and configured to transfer charges generated by the photoelectric conversion portion; a first film having a part provided above the photoelectric conversion portion; a second film provided on the first film; and a contact plug being in contact with the second film and connected to the transfer transistor, wherein the part of the first film is located between the second film and the photoelectric conversion portion, wherein the first film has an end portion between the part of the first film and a side face of the gate electrode on the photoelectric conversion side, and wherein a portion of the second film is located between the end portion and the gate electrode.

According to further another aspect of the present invention, provided is a manufacturing method of a photoelectric conversion apparatus, the manufacturing method including steps of: forming a silicon nitride film on a region on a substrate including a photoelectric conversion portion, and a transfer transistor that includes a gate electrode and transfers charges generated by the photoelectric conversion portion, wherein the region includes at least a photoelectric conversion portion; and making the silicon nitride film discontinuous on the photoelectric conversion portion side of a side face of the gate electrode on the photoelectric conversion portion side.

Further features of the present invention will become apparent from the following description of exemplary embodiments with reference to the attached drawings.

### BRIEF DESCRIPTION OF THE DRAWINGS

FIG. 1 is a block diagram illustrating a general configuration of a photoelectric conversion apparatus according to a first embodiment of the present invention.

FIG. 2 is a circuit diagram illustrating a configuration example of a pixel of the photoelectric conversion apparatus according to the first embodiment of the present invention.

FIG. 3 is a schematic diagram illustrating an arrangement example of each block of the photoelectric conversion apparatus according to the embodiment of the present invention.

FIG. 4 is a schematic sectional view illustrating the structure of a pixel of the photoelectric conversion apparatus according to the first embodiment of the present invention.

FIG. 5 is a diagram illustrating a parasitic capacitance coupled to a floating diffusion portion.

FIG. 6 is a diagram illustrating a setting example of a range in which a relative dielectric constant of an insulating film is defined.

FIGS. 7A, 7B, 7C, 7D and 7E are process sectional views (part 1) illustrating a manufacturing method of the photoelectric conversion apparatus according to the first embodiment of the present invention.

FIGS. 8A, 8B and 8C are process sectional views (part 2) illustrating a manufacturing method of the photoelectric conversion apparatus according to the first embodiment of the present invention.

FIG. 9 is a schematic sectional view illustrating the structure of a pixel of a photoelectric conversion apparatus according to a second embodiment of the present invention.

FIGS. 10A, 10B and 10C are process sectional views illustrating a manufacturing method of the photoelectric conversion apparatus according to the second embodiment of the present invention.

FIG. 11 is a block diagram illustrating a general configuration of an imaging system according to a third embodiment of the present invention.

FIGS. 12A and 12B are diagrams illustrating configuration examples of an imaging system and a moving body according to a fourth embodiment of the present invention.

FIG. 13 is a plan view illustrating the configuration of a photoelectric conversion apparatus according to a fifth embodiment of the present invention.

FIG. 14 is a circuit diagram illustrating a pixel of the photoelectric conversion apparatus according to the fifth embodiment of the present invention.

FIGS. 15A, 15B and 15C are diagrams illustrating a part of the pixel in the photoelectric conversion apparatus according to the fifth embodiment of the present invention.

FIG. 16 is a plan view illustrating an example of a layout of pixels in the photoelectric conversion apparatus according to the fifth embodiment of the present invention.

FIG. 17 is a graph illustrating a result obtained by measuring an increase amount of dark output after light irradiation for the photoelectric conversion apparatus according to the fifth embodiment of the present invention.

FIGS. 18A and 18B are diagrams illustrating a part of a pixel in a photoelectric conversion apparatus according to a comparative example.

FIGS. 19A, 19B and 19C are sectional views illustrating a manufacturing method of the photoelectric conversion apparatus according to the fifth embodiment of the present invention.

FIGS. 20A, 20B and 20C are sectional views illustrating a manufacturing method of the photoelectric conversion apparatus according to the fifth embodiment of the present invention.

FIGS. 21A, 21B and 21C are sectional views illustrating a manufacturing method of the photoelectric conversion apparatus according to the fifth embodiment of the present invention.

FIGS. 22A and 22B are sectional views illustrating a manufacturing method of the photoelectric conversion apparatus according to the fifth embodiment of the present invention.

FIGS. 23A and 23B are schematic diagrams illustrating a part of a pixel in a photoelectric conversion apparatus according to a sixth embodiment of the present invention.

FIG. 24 is a block diagram illustrating a general configuration of an imaging system according to a seventh embodiment of the present invention.

FIGS. 25A and 25B are diagrams illustrating configuration examples of an imaging system and a moving body according to an eighth embodiment of the present invention.

### DESCRIPTION OF THE EMBODIMENTS

### First Embodiment

In the conventional photoelectric conversion apparatus, however, a silicon nitride film that functions as an anti-reflection film is provided over the whole pixel region. Since silicon nitride has a higher relative dielectric constant than silicon oxide widely used for an interlayer insulating film or the like, the parasitic capacitance formed between a transfer gate and a floating diffusion portion via such a silicon nitride film increases, and this causes an increase of random noise.

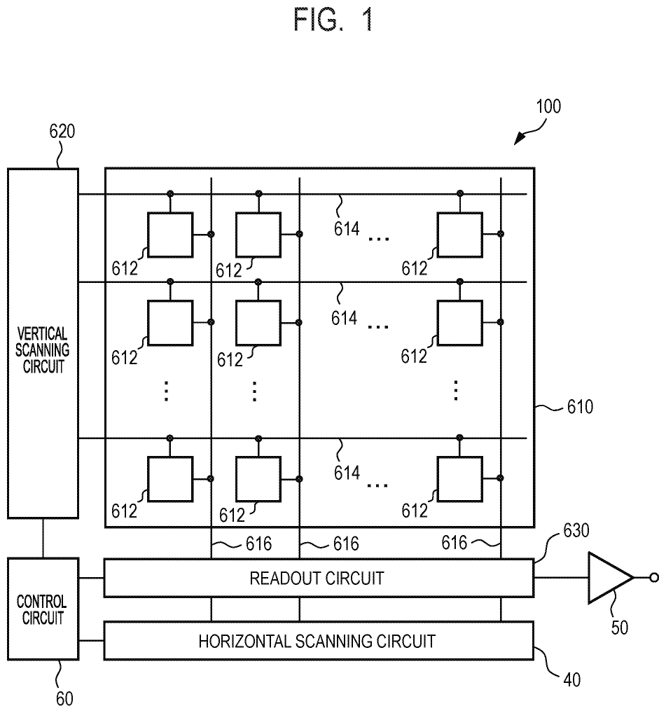

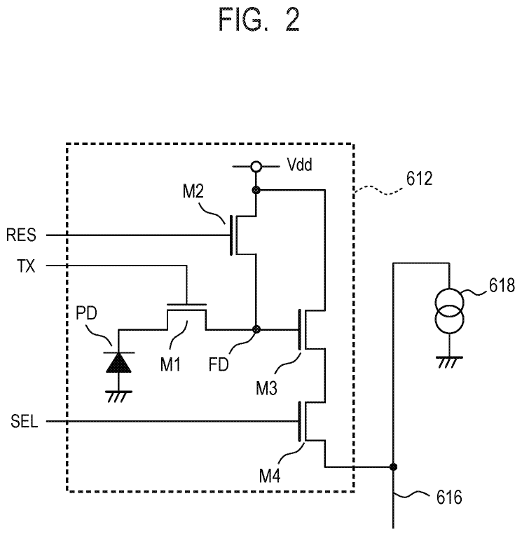

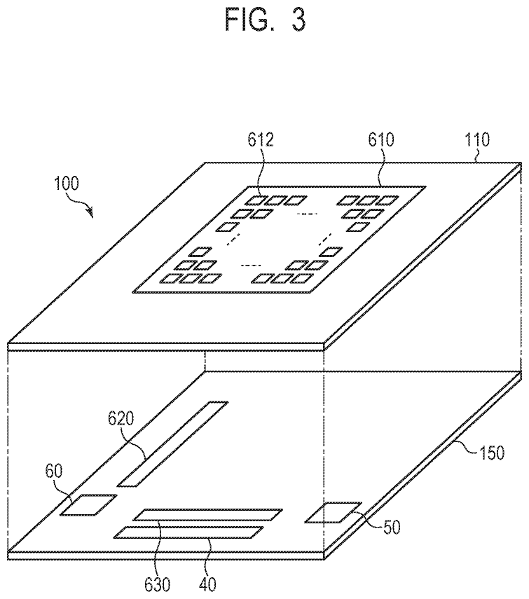

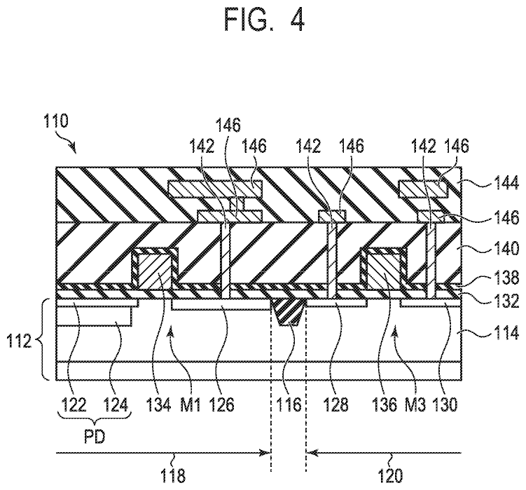

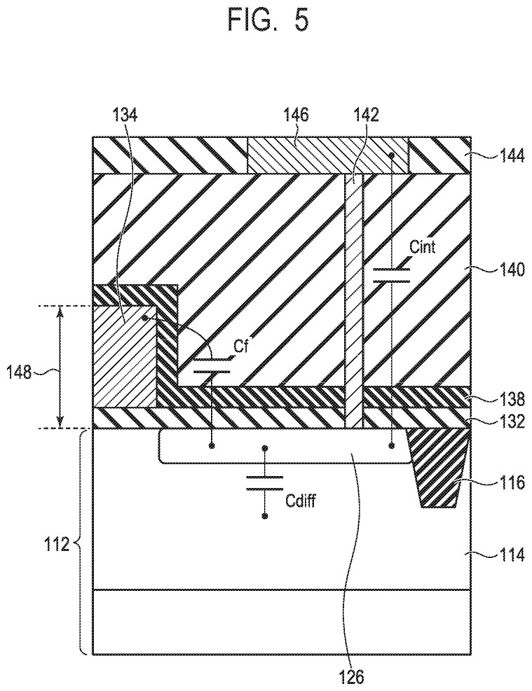

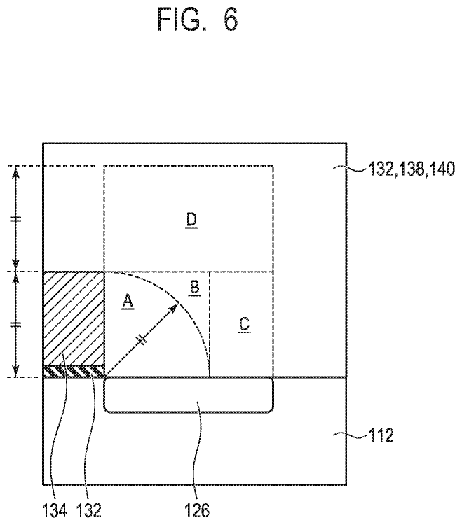

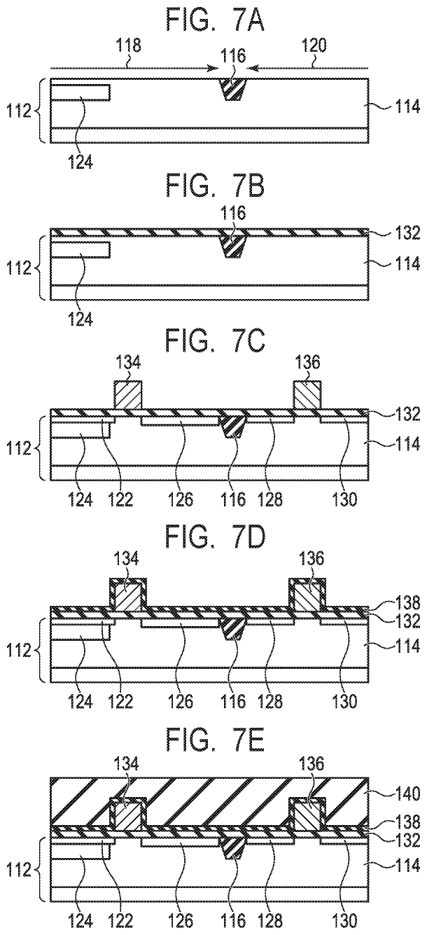

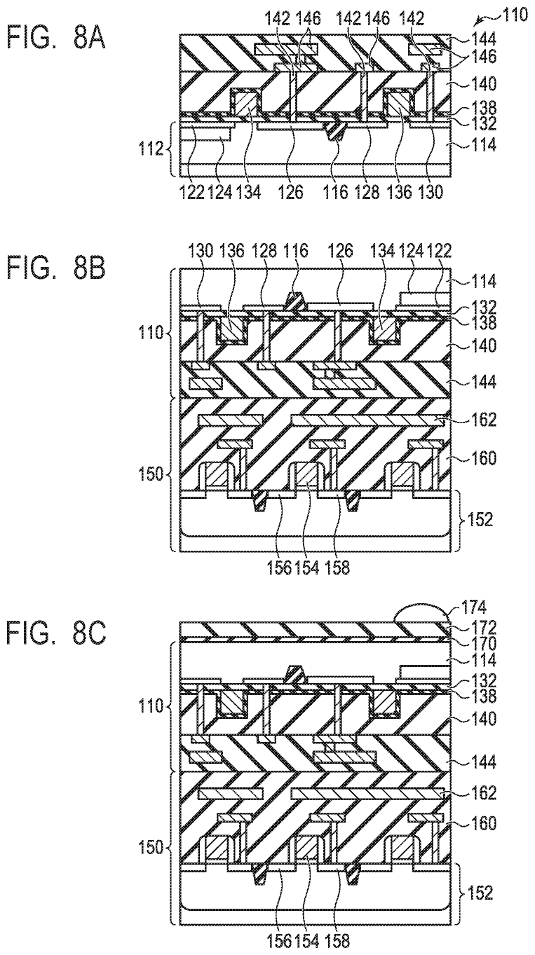

The present disclosure intends to provide a photoelectric conversion apparatus that can reduce a parasitic capacitance coupled to a floating diffusion portion and reduce noise superimposed on an output signal. A photoelectric conversion apparatus and a manufacturing method thereof according to a first embodiment of the present disclosure will be described with reference to FIG. 1 to FIG. 8C. FIG. 1 is a block diagram illustrating a general configuration of a photoelectric conversion apparatus according to the present embodiment. FIG. 2 is a circuit diagram illustrating a configuration example of a pixel of the photoelectric conversion apparatus according to the present embodiment. FIG. 3 is a schematic diagram illustrating an arrangement example of each block of the photoelectric conversion apparatus according to the present embodiment. FIG. 4 is a schematic sectional view illustrating the structure of a pixel of the photoelectric conversion apparatus according to the present embodiment. FIG. 5 is a diagram illustrating a parasitic capacitance coupled to a floating diffusion portion. FIG. 6 is a diagram illustrating a setting example of a range in which a relative dielectric constant of an insulating film is defined. FIG. 7A to FIG. 8C are process sectional views illustrating a manufacturing method of the photoelectric conversion apparatus according to the present embodiment.

As illustrated in FIG. 1, a photoelectric conversion apparatus 100 according to the present embodiment has a pixel region 610, a vertical scanning circuit 620, a readout circuit 630, a horizontal scanning circuit 40, an output circuit 50, and a control circuit 60.

In the pixel region 610, a plurality of pixels 612 arranged in a matrix are provided over a plurality of rows and a plurality of columns. Each of the pixels 612 includes a photoelectric conversion portion formed of a photoelectric conversion element such as a photodiode and outputs a pixel signal in accordance with the light amount of an incident light. The number of rows and the number of columns of the pixel array arranged in the pixel region 610 are not particularly limited. Further, in the pixel region 610, an optical black pixel whose photoelectric conversion portion is shielded from light, a dummy pixel that does not output a signal, or the like may be arranged in addition to effective pixels that output pixel signals in accordance with the light amount of an incident light.

On each row of the pixel array of the pixel region 610, a control line 614 is arranged extending in a first direction (the horizontal direction in FIG. 1). Each of the control lines 614 is connected to the pixels 612 aligned in the first direction, respectively, to form a signal line common to these pixels 612. The first direction in which the control line 614 extends may be referred to as the row direction or the horizontal direction. The control lines 614 are connected to the vertical scanning circuit 620.

On each column of the pixel array of the pixel region 610, an output line 616 is arranged extending in a second direction (the vertical direction in FIG. 1) intersecting the first direction. Each of the output lines 616 is connected to the pixels 612 aligned in the second direction, respectively, to form a signal line common to these pixels 612. The second direction in which the output line 616 extends may be referred to as the column direction or the vertical direction. The output lines 616 are connected to the readout circuit 630.

The vertical scanning circuit 620 is a control circuit unit that supplies, to the pixels 612 via the control lines 614 provided on respective rows of the pixel array, control signals used for driving readout circuits in the pixels 612 when signals are read out from the pixels 612. The vertical scanning circuit 620 can be formed by using a shift register or an address decoder. Signals read out from the pixels 612 on a row basis are input to the readout circuit 630 via the output lines 616 provided on respective columns of the pixel array.

The readout circuit 630 is a circuit unit that implements predetermined signal processing, for example, signal processing such as an amplification process, an analog-to-digital (A/D) conversion process, or the like on a signal read out from the pixels 612 on each column via the output line 616. The readout circuit 630 may include a signal holding unit, a column amplifier, a correlated double sampling (CDS) circuit, an adder circuit, an A/D converter circuit, a column memory, or the like.

The horizontal scanning circuit 40 is a circuit unit that supplies, to the readout circuit 630, control signals used for transferring signals processed by the readout circuit 630 to the output circuit 50 sequentially on a column basis. The horizontal scanning circuit 40 can be formed by using a shift register or an address decoder. The output circuit 50 is a circuit unit that is formed of a buffer amplifier, a differential amplifier, or the like and amplifies and outputs a signal of a column selected by the horizontal scanning circuit 40.

The control circuit 60 is a circuit unit that supplies, to the vertical scanning circuit 620, the readout circuit 630, and the horizontal scanning circuit 40, control signals used for controlling the operations of the above or the timings thereof. Some or all of the control signals supplied to the vertical scanning circuit 620, the readout circuit 630, and the horizontal scanning circuit 40 may be supplied from the outside of the photoelectric conversion apparatus 100.

As illustrated in FIG. 2, for example, each of the pixels 612 may be formed of a photoelectric conversion portion PD, a transfer transistor M1, a reset transistor M2, an amplifier transistor M3, and a select transistor M4.

The photoelectric conversion portion PD is a photodiode, for example, the anode is connected to a ground node, and the cathode is connected to the source of the transfer transistor M1. The drain of the transfer transistor M1 is connected to the source of the reset transistor M2 and the gate of the amplifier transistor M3. The connection node of the drain of the transfer transistor M1, the source of the reset transistor M2, and the gate of the amplifier transistor M3 is a so-called a floating diffusion portion FD. The floating diffusion portion FD includes a capacitance component (floating diffusion capacitance) and has a function as a charge holding portion.

The drain of the reset transistor M2 and the drain of the amplifier transistor M3 are connected to a power source node to which a voltage Vdd is supplied. The source of the amplifier transistor M3 is connected to the drain of the select transistor M4. The source of the select transistor M4 is connected to the output line 616. The output line 616 is connected to the current source 618.

In the case of the pixel configuration illustrated in FIG. 2, the control line 614 on each row arranged in the pixel region 610 includes a transfer gate signal line TX, a reset signal line RES, and a select signal line SEL. The transfer gate signal line TX is connected to the gates of the transfer transistors M1 of the pixels 612 belonging to a corresponding row. The reset signal line RES is connected to the gates of the reset transistors M2 of the pixels 612 belonging to a corresponding row. The select signal line SEL is connected to the gates of the select transistors M4 of the pixels 612 belonging to a corresponding row.

The photoelectric conversion portion PD converts (photoelectrically converts) an incident light into an amount of charges in accordance with a light amount and accumulates the generated charges. When turned on, the transfer transistor M1 transfers charges held in the photoelectric conversion portion PD to the floating diffusion portion FD. The floating diffusion portion FD has a voltage corresponding to the amount of charges transferred from the photoelectric conversion portion PD in accordance with charge-to-voltage conversion caused by the capacitance thereof. The amplifier transistor M3 is configured such that the voltage Vdd is supplied to the drain and a bias current is supplied to the source from the current source 618 via the select transistor M4 and forms an amplifier unit (source follower circuit) whose gate is the input node. Thereby, the amplifier transistor M3 outputs a signal based on the voltage of the floating diffusion portion FD to the output line 616 via the select transistor M4. When turned on, the reset transistor M2 resets the floating diffusion portion FD to a voltage in accordance with the voltage Vdd.

As illustrated in FIG. 3, for example, the photoelectric conversion apparatus 100 according to the present embodiment can be formed by dividing the blocks illustrated in FIG. 1 into two substrates 110 and 150 and joining the substrates 110 and 150 to each other. The substrate 110 and the substrate 150 may be electrically connected to each other via a conductive member such as a bump electrode, a through electrode, or the like, for example.

FIG. 3 illustrates a configuration example when the pixel region 610 of the blocks illustrated in FIG. 1 is arranged on the upper substrate 110 and the vertical scanning circuit 620, the readout circuit 630, the horizontal scanning circuit 40, the output circuit 50, and the control circuit 60 of the blocks are arranged on the under substrate 150. The vertical scanning circuit 620, the readout circuit 630, the horizontal scanning circuit 40, the output circuit 50, and the control circuit 60 form a peripheral circuit used for controlling readout of signals from the pixel region 610.

In the configuration example illustrated in FIG. 3, a control signal from the vertical scanning circuit 620 on the substrate 150 is transmitted to the substrate 110 to drive the pixels 612 of the pixel region 610 on the substrate 110. An output signal from the pixel region 610 is transmitted to the substrate 150 and processed in the readout circuit 630 on the substrate 150. Then, a digital signal on a column whose address is designated by the horizontal scanning circuit 40 on the substrate 150 is processed in the output circuit 50 on the substrate 150 and output to the outside of the photoelectric conversion apparatus 100.

Note that it is not necessarily required to arrange only the pixel region 610 on the substrate 110. For example, any one or more of the vertical scanning circuit 620, the readout circuit 630, the horizontal scanning circuit 40, the output circuit 50, and the control circuit 60 may be arranged on the substrate 110, or some of these components may be arranged on the substrate 110. The former may be an example in which the pixel region 610 and the vertical scanning circuit 620 are arranged on the substrate 110, for example. The latter may be an example in which the pixel region 610 and a part of the readout circuit 630 are arranged on the substrate 110, for example. Further, a circuit other than the blocks illustrated in FIG. 1, for example, a signal processing circuit or the like that performs predetermined signal processing on a signal output from the output circuit 50 may be arranged on the substrate 150.

FIG. 4 is a sectional view illustrating the structure of the substrate 110 of the photoelectric conversion apparatus 100. FIG. 4 illustrates the photoelectric conversion portion PD, the transfer transistor M1, and the amplifier transistor M3 out of the components of the pixel 612 provided in the substrate 110.

A semiconductor region 114 of a second conductivity type (for example, p-type) forming a well is provided in the surface part of the silicon substrate 112 of a first conductivity type (for example, n-type). An element isolation region 116 defining active regions 118 and 120 is provided in the surface part of the semiconductor region 114. The element isolation region 116 is formed of a structure made of a dielectric material formed by a shallow trench isolation (STI) method, a local oxidation of silicon (LOCOS) method, or the like.

For example, the photoelectric conversion portion PD and the transfer transistor M1 out of the components of the pixel 612 are provided in the active region 118. Further, the reset transistor M2, the amplifier transistor M3, and the select transistor M4 out of the components of the pixel 612 are provided in the active region 120. In FIG. 4, only the amplifier transistor M3 is illustrated out of the transistors arranged in the active region 120.

The photoelectric conversion portion PD is an embedded photodiode including a semiconductor region 122 of the second conductivity type provided in contact with the surface of the silicon substrate 112 and a semiconductor region 124 of the first conductivity type provided under the semiconductor region 122. The semiconductor region 124 forms p-n junction with the semiconductor region 122. The semiconductor region 124 has a roll as a charge accumulation layer that accumulates signal charges (electrons) generated by the photoelectric conversion portion PD. The semiconductor region 122 has a roll as a surface protection layer that suppresses a surface leak current. The semiconductor region 126 of the first conductivity type forming a part of the floating diffusion portion FD is provided on the surface part of the active region 118 so as to be spaced apart from the semiconductor region 124.

A gate electrode 134 made of a conductive material such as poly-crystal silicon or the like is provided above the silicon substrate 112 between the semiconductor region 124 and the semiconductor region 126 via a gate insulating film 132 made of silicon oxide (SiO), silicon oxy nitride (SiON), or the like. Thereby, the transfer transistor M1 in which the semiconductor region 124 is the source, the semiconductor region 126 is the drain, and the gate electrode 134 is the gate is configured.

A semiconductor region 128 of the first conductivity type and a semiconductor region 130 of the first conductivity type are provided so as to be spaced apart from each other on the surface part of the active region 120.

A gate electrode 136 made of a conductive material such as poly-crystal silicon or the like is provided above the silicon substrate 112 between the semiconductor region 128 and the semiconductor region 130 via the gate insulating film 132 made of SiO, SiON, or the like. Thereby, the amplifier transistor M3 in which the semiconductor region 128 is the source, the semiconductor region 130 is the drain, and the gate electrode 136 is the gate is configured.

An insulating film 138 and an insulating film 140 are provided above the silicon substrate 112 in which the photoelectric conversion portion PD, the transfer transistor M1, the amplifier transistor M3, and the like are provided. The insulating film 138 is formed along the unevenness formed above the surface of the silicon substrate 112 due to the gate electrodes 134 and 136. The film thickness of the insulating film 138 is thinner than a thickness corresponding to the height of the gate electrodes 134 and 136. The insulating film 138 may be formed of a porous insulating material such as nano-clustering silica, a low dielectric constant material such as silicon oxy carbide (SiOC), silicon oxide, or the like. The insulating film 138 may be formed of stacked films of a silicon oxide film and a low dielectric constant film. The insulating film 140 is formed to have a film thickness sufficient to fill the unevenness above the surface of the silicon substrate 112, and the surface is planarized. In other words, the insulating film 140 is at least partially located at a position closer to the silicon substrate 112 than the upper face of the gate electrodes 134 and 136. The insulating film 140 may be formed of silicon oxide. It is desirable that the dielectric constant of the insulating film 138 be smaller than the dielectric constant of the insulating film 140.

Note that, although FIG. 4 illustrates a state where the gate insulating film 132 extends between the silicon substrate 112 and the insulating film 138, the gate insulating film 132 is at least provided between the gate electrodes 134 and 136 and the silicon substrate 112. That is, in a region except a region in which the gate electrodes 134 and 136 are provided, the under part of the insulating film 138 may be directly contacted to a film other than the gate insulating film 132 or to the silicon substrate 112.

Contact plugs 142 electrically connected to the semiconductor regions 126, 128, and 130 are provided through the insulating films 140 and 138 and the gate insulating film 132. The contact plug 142 may be formed of a barrier metal of titanium nitride or the like and tungsten, for example.

An insulating film 144 is provided on the insulating film 140. Wiring layers 146 electrically connected to the transfer transistor M1, the amplifier transistor M3, or the like via the contact plugs 142 are provided in the insulating film 144. The wiring layer 146 may be formed of aluminum or copper, for example.

Note that the photoelectric conversion apparatus of the present embodiment is a backside irradiation photoelectric conversion apparatus. That is, the photoelectric conversion portion PD receives an incident light from a face (the underside in FIG. 4) opposed to a face (the upper side in FIG. 4) of the silicon substrate 112 on the side where the pixel 612 is provided. Therefore, an anti-reflection film is unnecessary on the face of the silicon substrate 112 side where the pixel 612 is provided.

FIG. 5 is an enlarged sectional view near the semiconductor region 126 forming the floating diffusion portion FD. As illustrated in FIG. 5, a representative parasitic capacitance coupled to the semiconductor region 126 may be a p-n junction capacitance Cdiff coupled to the semiconductor region 114, an interlayer capacitance Cint coupled to the wiring layer 146, and a capacitance Cf coupled to the gate electrode 134.

It is desirable to reduce the parasitic capacitance of the floating diffusion portion FD in terms of reducing random noise to improve the S/N ratio. On the other hand, in a typical front side irradiation imaging apparatus, a SiN film or a SiON film is used as an anti-reflection film arranged above a photoelectric conversion portion, an increase in the capacitance Cf or the interlayer capacitance Cint is unavoidable. That is, compared to the relative dielectric constant of around 3.8 for SiO, the relative dielectric constant of SiN is around 7.0, and the relative dielectric constant of SiON is around 5.0 to 7.0. Thus, when the insulating film 138 is formed of these insulating materials having a relatively high dielectric constant, the capacitance Cf or the interlayer capacitance Cint will increase.

In this regard, in the photoelectric conversion apparatus of the present embodiment, the insulating film 138 is formed of an insulating material having a lower dielectric constant than SiN or SiON, specifically, a lower dielectric constant material such as SiOC or a porous insulating material or SiO. Therefore, the capacitance Cf or the interlayer capacitance Cint can be reduced compared to a case where the insulating film 138 is formed of SiN or SiON, and the S/N ratio can be improved by a reduction of the FD capacitance. In terms of reducing the capacitance Cf, the insulating film 138 covers at least the side face of the gate electrode 134 of the transfer transistor M1 on the floating diffusion portion FD side.

Further, SiON may be used for the gate insulating film 132 for suppressing an increase of a tunnel current or suppressing penetration of an impurity through the gate electrode 134 in a direction of the silicon substrate 112. However, since the dielectric constant of SiON increases as the nitrogen concentration increases, this may cause the gate insulating film 132 to increase the capacitance Cf.

In terms of the above, it is desirable that the relative dielectric constant of an insulating material forming the insulating film (the gate insulating film 132, the insulating films 138 and 140) formed in a range 148 from the surface of the silicon substrate 112 to the upper face of the gate electrode 134 be lower than 5.0. Note that the nitrogen concentration in SiON having a relative dielectric constant of around 5.0 is approximately 10 atm %.

Although the range in which an insulating film is to be formed so as not to contain an insulating material having a relative dielectric constant of 5.0 or higher may change in accordance with the relationship to the stack structure of insulating films or another structure and thus is not necessarily even, the range can be defined based on the geometrical relationship illustrated in FIG. 6, for example. Each of the following first to fourth ranges includes at least a part of a spatial range between the gate electrode 134 and the floating diffusion portion FD.

The first range is a range (region A in FIG. 6) in which the distance from the intersection line including the side face of the gate electrode 134 on the floating diffusion portion FD (the semiconductor region 126) side and the surface of the silicon substrate 112 is less than or equal to the distance corresponding to the height of the gate electrode 134. The second range is a range (region A+B in FIG. 6) which is from the surface of the silicon substrate 112 up to the height of the upper face of the gate electrode 134 and in which the distance from the side face of the gate electrode 134 is less than or equal to the distance corresponding to the height of the gate electrode 134. The third range is a range (region A+B+C in FIG. 6) which is from the surface of the silicon substrate 112 to the height of the upper face of the gate electrode 134 and overlaps the floating diffusion portion FD in plan view. The fourth range is a range (region A+B+C+D in FIG. 6) which is from the surface of the silicon substrate 112 up to a height that is twice the height of the upper face of the gate electrode 134 and overlaps the floating diffusion portion FD in plan view. Note that the term of plan view as used herein corresponds to a projection drawing viewed from the normal direction of the silicon substrate 112.

The range in which the relative dielectric constant of the insulating material is set to be lower than 5.0 preferably includes at least the first range described above and more preferably includes the second range described above. Further, the range in which the relative dielectric constant of the insulating material is set to be lower than 5.0 more preferably includes the third range described above and more preferably includes the fourth range described above. The photoelectric conversion apparatus may include the insulating material having a relative dielectric constant of 5.0 or higher outside the first range from the surface of the silicon substrate 112, preferably outside the second range, more preferably outside the third range, and more preferably outside the fourth range. For example, the insulating material having a relative dielectric constant of 5.0 or higher may be included outside the fourth range, that is, a position distant by a length that is twice or more the height of the upper face of the gate electrode. The insulating material having a relative dielectric constant of 5.0 or higher may be, for example, silicon nitride or silicon carbide. The member made of the insulating material having a relative dielectric constant of 5.0 or higher may be used as an etching stop member, a member used for suppressing diffusion of a metal, or a passivation member, for example.

The insulating film 140 may be formed of SiO. It is desirable to form the insulating film 140 by a high density plasma chemical vapor deposition (HDPCVD) method in terms of improving the filling property of a space between the gate electrodes 134 and 136 or the like. Since a SiO film deposited by the HDPCVD method has high permeability of hydrogen and has a large content of hydrogen in the film, such a SiO film is useful for a photoelectric conversion apparatus in terms of noise reduction. The SiO film formed by the HDPCVD method may contain argon in plasma and thus has a higher argon concentration than the insulating film 138 or a SiO film formed by a thermal CVD method or a typical plasma CVD method.

In general, however, plasma damage is likely to occur in deposition by the HDPCVD method, and it is not preferable to deposit the insulating film 140 directly on the gate electrodes 134 and 136 because reliability of the gate insulating film 132 may be reduced. The insulating film 138 arranged between the gate electrodes 134 and 136 and the insulating film 140 also has a roll as a protection film that reduces plasma damage during deposition of the insulating film 140. That is, it is desirable that the entire upper faces and side faces of the gate electrodes 134 and 136 be covered with the insulating film 138 at least when the insulating film 140 is deposited.

While the transfer transistor M1 and the amplifier transistor M3 are described here, plasma damage similarly affects the reset transistor M2 or the select transistor M4, and the insulating film 138 is formed also on the gate electrodes of these transistors.

Next, a manufacturing method of a photoelectric conversion apparatus according to the present embodiment will be described with reference to FIG. 7A to FIG. 8C. FIG. 7A to FIG. 8C are process sectional views illustrating the manufacturing method of the photoelectric conversion apparatus according to the present embodiment.

First, the element isolation region 116 that defines the active regions 118 and 120 is formed in the primary surface of the silicon substrate 112 of the first conductivity type (n-type) by using an STI method, a LOCOS method, or the like.

Next, the semiconductor region 114 of the second conductivity type (p-type) that is to be a well is formed inside the silicon substrate 112 of the active regions 118 and 120 by using photolithography and ion implantation. Further, the semiconductor region 124 of the first conductivity type that is to be a charge accumulation region of the photoelectric conversion portion PD is formed in a formation region of the photoelectric conversion portion PD (FIG. 7A).

Next, after the silicon substrate 112 is thermally oxidized to form a silicon oxide film, a nitriding process is performed, and the gate insulating film 132 made of silicon oxy nitride (SiON) is formed on the silicon substrate 112 (FIG. 7B). The nitriding process of a silicon oxide film may be performed by a thermal nitriding method or may be performed by a plasma nitriding method. Such a nitriding process may cause the gate insulating film 132 to be silicon oxide containing nitrogen. At this time, nitriding process conditions are set as appropriate so that the nitrogen concentration in the gate insulating film 132 is less than 10 atm %.

Next, a poly-crystal silicon film is deposited on the gate insulating film 132 by using a CVD method, for example, and this poly-crystal silicon film is then patterned by using photolithography and dry etching to form the gate electrodes 134 and 136 made of poly-crystal silicon. After the gate electrodes 134 and 136 are formed, at least a part of the gate insulating film 132 provided in a region except a region directly under the gate electrodes 134 and 136 may be removed by wet etching or the like.

Next, the semiconductor region 122 of the second conductivity type that is to be a surface protection layer of the photoelectric conversion portion PD and the semiconductor region 126 of the first conductivity type forming the floating diffusion portion FD are formed in the active region 118 by using photolithography and ion implantation. Further, the semiconductor regions 128 and 130 of the first conductivity type that are to be source/drain regions of the amplifier transistor M3 are formed in the active region 120 (FIG. 7C).

Next, a thermal process at 800 degrees Celsius to 1100 degrees Celsius is performed in a nitrogen atmosphere if necessary, and a recovery process of a crystal defect introduced in the silicon substrate 112 is performed by ion implantation.

Next, the insulating film 138 made of a low dielectric constant material such as silicon oxy carbide (SiOC) or a porous insulating material or silicon oxide is formed by a low pressure CVD method or a plasma CVD method, for example (FIG. 7D). It is desirable to apply a deposition method causing less plasma damage to the deposition of the insulating film 138 in terms of suppressing a reduction of reliability of the gate insulating film 132.

Next, the insulating film 140 made of silicon oxide is formed by an HDPCVD method, for example (FIG. 7E). As described previously, it is desirable that the insulating film 140 be formed by the HDPCVD method in terms of improvement of embedding property of the space between the gate electrodes 134 and 136 and the like or a content of hydrogen. The insulating film 140 may be planarized by a CMP method or the like if necessary.

Next, contact holes that penetrate the insulating films 140 and 138 and the gate insulating film 132 and reach the silicon substrate 112 are formed by photolithography and dry etching. Next, a bather metal film of a titanium nitride (TiN) or the like and a tungsten (W) film are formed by a CVD method or the like, for example, these conductive films on the insulating film 140 are then removed by a CMP method or the like, and thereby the contact plugs 142 embedded in the contact holes are formed.

Next, the wiring layers 146 provided inside the insulating film 144 are formed by using a known multilayer wiring process on the insulating film 140 in which the contact plugs 142 are provided. The wiring layers 146 are formed with a predetermined total number of layers being stacked via the insulating film 144 and electrically connected to the transfer transistor M1, the amplifier transistor M3, and the like via the contact plugs 142. The insulating film 144 may be formed of stacked films of silicon oxide and silicon oxy carbide, for example. Further, the wiring layer 146 may be formed of aluminum or copper, for example.

As described above, the substrate 110 in which the pixel region 610 is provided on the silicon substrate 112 is formed (FIG. 8A).

Further, the substrate 150 which is a separate substrate from the substrate 110 and in which the vertical scanning circuit 620, the readout circuit 630, the horizontal scanning circuit 40, the output circuit 50, the control circuit 60, and the like are provided is formed by using a known manufacturing process for a semiconductor apparatus. As an example, as illustrated in FIG. 8B and FIG. 8C, the substrate 150 provided with an insulating film 160 in which a wiring layer 162 is arranged is here assumed to be provided on a silicon substrate 152 in which a transistor including the gate electrode 154 and the source/drain regions 156 and 158 is provided.

Next, the substrate 110 and the substrate 150 formed in such a way are attached to each other so that the insulating film 144 and the insulating film 160 face each other by using a known substrate attaching technique. Thereby, the substrate 110 and the substrate 150 are physically and electrically joined to each other.

Next, the substrate 110 attached on the substrate 150 is grinded from the silicon substrate 112 side to thin the substrate 110 to a thickness suitable for light incidence to the photoelectric conversion portion PD (FIG. 8B). A known substrate thinning technique such as a CMP method can be applied to the thinning process of the substrate 110.

Next, insulating films 170, 172, and 174 are formed on the surface of the substrate 110 on which the thinning process has been performed (FIG. 8C). It is desirable that the insulating film 170 be formed of an insulating material having negative fixed charges, such as aluminum oxide, for example. The insulating film 172 may be formed of an insulating material such as silicon oxide, for example. The insulating film 174 is molded in a lens shape and structured to collect light into the photoelectric conversion portion PD. The insulating film 174 may be formed of silicon nitride or the like, for example.

A color filter, a micro-lens, or the like are then formed if necessary, and the photoelectric conversion apparatus according to the present embodiment is completed.

As described above, according to the present embodiment, the parasitic capacitance coupled to a floating diffusion portion can be reduced, and noise superimposed on an output signal can be reduced.

### Second Embodiment

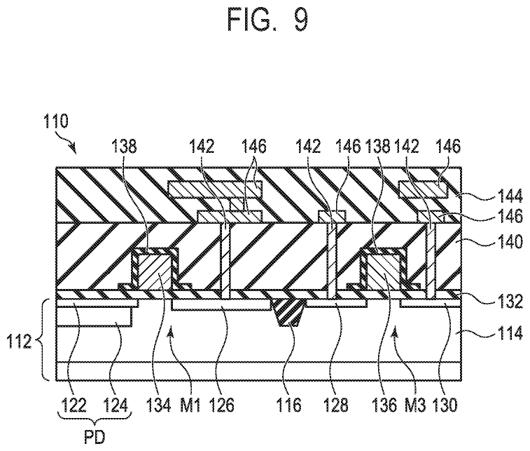

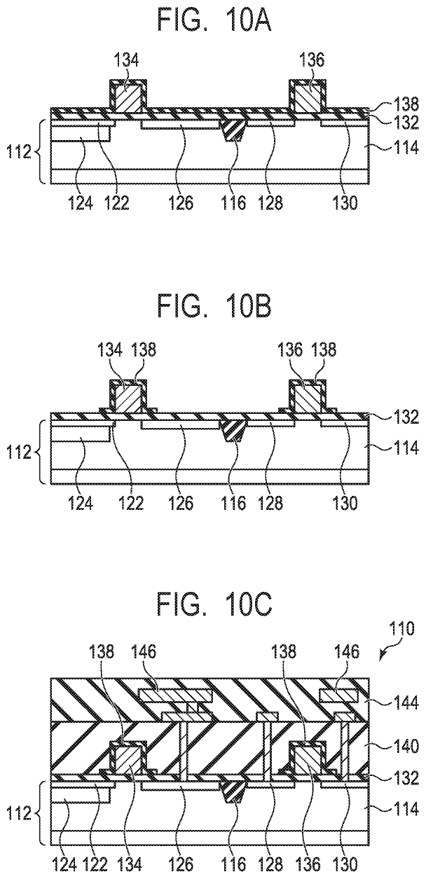

A photoelectric conversion apparatus and a manufacturing method thereof according to a second embodiment of the present disclosure will be described with respect to FIG. 9 to FIG. 10C. FIG. 9 is a schematic sectional view illustrating the structure of a pixel of the photoelectric conversion apparatus according to the present embodiment. FIG. 10A to FIG. 10C are process sectional views illustrating the manufacturing method of the photoelectric conversion apparatus according to the present embodiment. The same components as those in the photoelectric conversion apparatus according to the first embodiment will be labeled with the same references, and the description thereof will be omitted or simplified.

First, the structure of the photoelectric conversion apparatus according to the present embodiment will be described with reference to FIG. 9. The photoelectric conversion apparatus 100 according to the present embodiment is the same as the photoelectric conversion apparatus according to the first embodiment except for different arrangement of the insulating film 138. That is, in the photoelectric conversion apparatus according to the present embodiment, as illustrated in FIG. 9, the insulating film 138 is provided so as to selectively cover the gate electrodes 134 and 136. In other words, the insulating film 140 has a portion directly contacting with the gate insulating film 132. Alternatively, when the gate insulating film 132 of a region except a part directly under the gate electrodes 134 and 136 is removed, the insulating film 140 has a portion directly contacting with the silicon substrate 112.

As described in the first embodiment, there is a concern that the insulating film 138 serves as a hydrogen diffusion suppression film when the insulating film 138 is formed of a low dielectric constant material such as SiOC or a porous insulating material or silicon oxide in terms of reducing a parasitic capacitance of the floating diffusion portion FD. That is, when the insulating film 138 is arranged over a wide region on the silicon substrate 112, supply of hydrogen from the insulating film 140 or a passivation film formed on the upper layer may be prevented by the insulating film 138, and there is a concern that a sufficient effect of reducing the interface state by hydrogen is not obtained.

On the other hand, the insulating film 138 has a roll of suppressing the gate insulating film 132 from being affected and damaged by charges flowing therein via the gate electrodes 134 and 136 at the time of forming the insulating film 140. That is, the insulating film 138 covers at least the gate electrodes 134 and 136.

In terms of the above, in the present embodiment, the insulating film 138 is formed so as to selectively cover the gate electrodes 134 and 136 to suppress the insulating film 138 from preventing supply of hydrogen from the insulating film 140 or the passivation film. With such a configuration of the photoelectric conversion apparatus, it is possible to obtain an effect of reducing the parasitic capacitance of the floating diffusion portion FD and an effect of reducing plasma damage at the time of forming the insulating film 140 as with the first embodiment while suppressing the insulating film 138 from preventing supply of hydrogen.

Note that, although the insulating film 138 is formed so as to selectively cover the gate electrodes 134 and 136 in the present embodiment, an opening may be provided in the insulating film 138 to facilitate supply of hydrogen via this opening. The insulating film 138 covers at least the gate electrodes 134 and 136, and a position where the opening is provided or the area of the opening can be set as appropriate in accordance with the effect of supply of hydrogen.

Next, the manufacturing method of the photoelectric conversion apparatus according to the present embodiment will be described with reference to FIG. 10A to FIG. 10C. First, in the same manner as the manufacturing method of the photoelectric conversion apparatus according to the first embodiment, the element isolation region 116, the semiconductor regions 124, 122, 126, 128, and 130, the gate insulating film 132, the gate electrodes 134 and 136, and the insulating film 138 are formed in and on the silicon substrate 112 (FIG. 10A).

Next, the insulating film 138 is patterned so as to selectively cover the gate electrodes 134 and 136 by using photolithography and dry etching. Alternatively, an opening is formed in the insulating film 138 so as not to expose the gate electrodes 134 and 136 (FIG. 10B).

Next, in the same manner as the manufacturing method of the photoelectric conversion apparatus according to the first embodiment, the insulating film 140, the contact plugs 142, the insulating film 144, the wiring layers 146, and the like are formed, and the substrate 110 is formed (FIG. 10C).

Then, in the same manner as the manufacturing method of the photoelectric conversion apparatus according to the first embodiment, the substrate 110 and the substrate 150 are joined to each other, and the photoelectric conversion apparatus of the present embodiment is then completed after a predetermined backend process.

As described above, according to the present embodiment, the parasitic capacitance coupled to the floating diffusion portion can be reduced, and noise superimposed on an output signal can be reduced.

### Third Embodiment

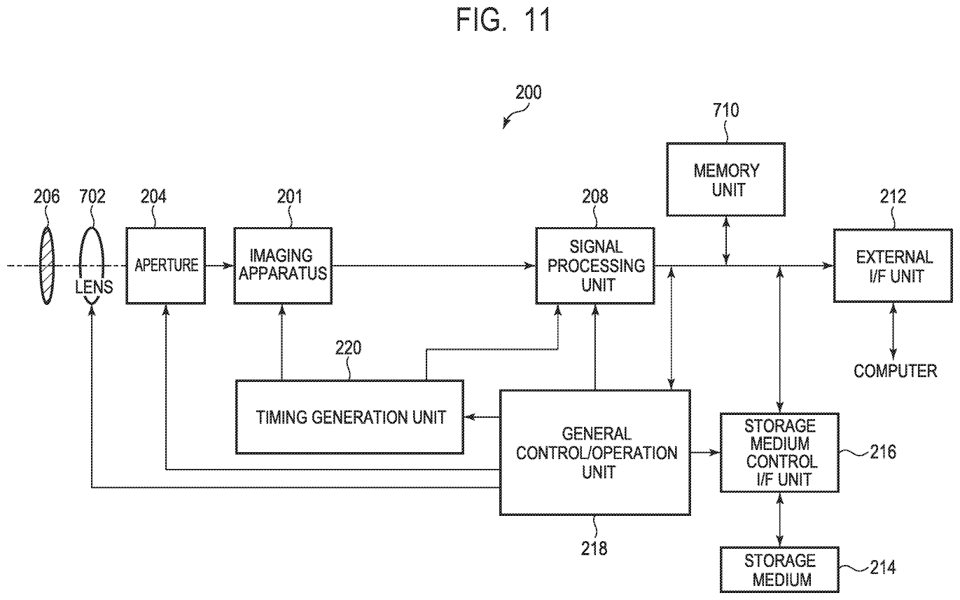

An imaging system according to a third embodiment of the present disclosure will be described with reference to FIG. 11. FIG. 11 is a block diagram illustrating a general configuration of the imaging system according to the present embodiment.

The photoelectric conversion apparatus 100 described in the above first and second embodiments is applicable to various imaging systems. An example of the applicable imaging system may be a digital still camera, a digital camcorder, a surveillance camera, a copy machine, a fax machine, a mobile phone, an on-vehicle camera, an observation satellite, or the like. Further, a camera module having an optical system such as a lens and an imaging apparatus is also included in the imaging system. FIG. 11 illustrates a block diagram of a digital still camera as one example of the above.

An imaging system 200 illustrated in FIG. 11 as an example has an imaging apparatus 201, a lens 702 that captures an optical image of an object on the imaging apparatus 201, an aperture 204 that changes the amount of light passing through the lens 702, and a barrier 206 that protects the lens 702. The lens 702 and the aperture 204 are an optical system that collects light into the imaging apparatus 201. The imaging apparatus 201 is a photoelectric conversion apparatus 100 described in any of the first and second embodiments and converts an optical image captured by the lens 702 into image data.

Further, the imaging system 200 has a signal processing unit 208 that performs a process of an output signal output from the imaging apparatus 201. The signal processing unit 208 performs AD conversion to convert an analog signal output from the imaging apparatus 201 into a digital signal. Further, the signal processing unit 208 performs operations to perform various correction or compression if necessary and output image data in addition to the above. The AD conversion unit that is a part of the signal processing unit 208 may be formed on a semiconductor substrate on which the imaging apparatus 201 is provided or may be formed on a semiconductor substrate other than a substrate on which the imaging apparatus 201 is provided. Further, the imaging apparatus 201 and the signal processing portion 208 may be formed on the same semiconductor substrate.

Furthermore, the imaging system 200 has a memory unit 710 used for temporarily storing image data and an external interface unit (external OF unit) 212 used for communicating with external computer or the like. Furthermore, the imaging system 200 has a storage medium 214 such as semiconductor memory used for performing storage or readout of imaging data and a storage medium control interface unit (storage medium control I/F unit) 216 used for performing storage or readout on the storage medium 214. Note that the storage medium 214 may be built in the imaging system 200 or may be removable.

Furthermore, the imaging system 200 has a general control/operation unit 218 that controls various operations and controls the entire digital still camera and a timing generation unit 220 that outputs various timing signals to the imaging apparatus 201 and the signal processing unit 208. Here, the timing signal or the like may be externally input, and the imaging system 200 has at least the imaging apparatus 201 and the signal processing unit 208 that processes an output signal output from the imaging apparatus 201.

The imaging apparatus 201 outputs an imaging signal to the signal processing unit 208. The signal processing unit 208 implements predetermined signal processing on an imaging signal output from the imaging apparatus 201 and outputs image data. The signal processing unit 208 uses an imaging signal to generate an image.

As described above, according to the present embodiment, the imaging system to which the photoelectric conversion apparatus 100 according to the first or second embodiment is applied can be realized.

### Fourth Embodiment

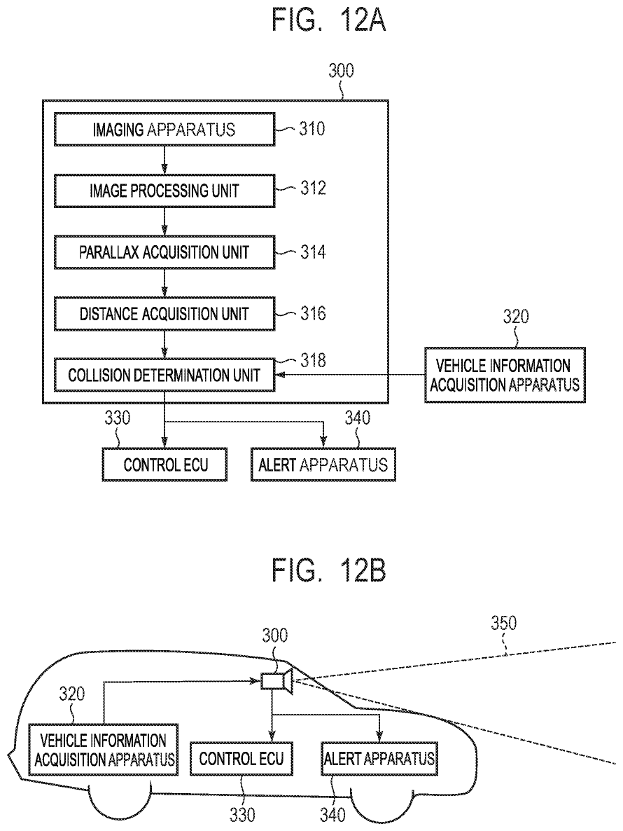

An imaging system and a moving body according to a fourth embodiment of the present disclosure will be described with reference to FIG. 12A and FIG. 12B. FIG. 12A and FIG. 12B are diagrams illustrating the configuration of the imaging system and the moving body according to the present embodiment.

FIG. 12A is a diagram illustrating an example of the imaging system regarding an on-vehicle camera. An imaging system 300 has an imaging apparatus 310. The imaging apparatus 310 is the photoelectric conversion apparatus 100 described in any of the above first and second embodiments. The imaging system 300 has an image processing unit 312 that performs image processing on a plurality of image data acquired by the imaging apparatus 310 and a parallax acquisition unit 314 that calculates a parallax (a phase difference of parallax images) from the plurality of image data acquired by the imaging system 300. Further, the imaging system 300 has a distance acquisition unit 316 that calculates a distance to the object based on the calculated parallax and a collision determination unit 318 that determines whether or not there is a collision possibility based on the calculated distance. Here, the parallax acquisition unit 314 and the distance acquisition unit 316 are an example of a distance information acquisition unit that acquires distance information on the distance to the object. That is, the distance information is information on a parallax, a defocus amount, a distance to an object, or the like. The collision determination unit 318 may use any of the distance information to determine the collision possibility. The distance information acquisition unit may be implemented by dedicatedly designed hardware or may be implemented by a software module. Further, the distance information acquisition unit may be implemented by a field programmable gate array (FPGA), an application specific integrated circuit (ASIC), or the like or may be implemented by a combination thereof.

The imaging system 300 is connected to the vehicle information acquisition apparatus 320 and can acquire vehicle information such as a vehicle speed, a yaw rate, a steering angle, or the like. Further, the imaging system 300 is connected to a control ECU 330, which is a control apparatus that outputs a control signal for causing a vehicle to generate braking force based on a determination result by the collision determination portion 318. Further, the imaging system 300 is also connected to an alert apparatus 340 that issues an alert to the driver based on a determination result by the collision determination portion 318. For example, when the collision probability is high as the determination result of the collision determination portion 318, the control ECU 330 performs vehicle control to avoid a collision or reduce damage by applying a brake, pushing back an accelerator, suppressing engine power, or the like. The alert apparatus 340 alerts a user by sounding an alert such as a sound, displaying alert information on a display of a car navigation system or the like, providing vibration to a seat belt or a steering wheel, or the like.

In the present embodiment, an area around a vehicle, for example, a front area or a rear area is captured by using the imaging system 300. FIG. 12B illustrates the imaging system when a front area of a vehicle (a capturing area 350) is captured. The vehicle information acquisition apparatus 320 transmits an instruction to the imaging system 300 or imaging apparatus 310. With such a configuration, ranging accuracy can be further improved.

Further, although the example of control for avoiding a collision to another vehicle has been described above in the present embodiment, the embodiment is applicable to automatic driving control for following another vehicle, automatic driving control for not going out of a traffic lane, or the like. Furthermore, the imaging system is not limited to a vehicle such as an automobile and can be applied to a moving body (moving equipment) such as a ship, an airplane, or an industrial robot, for example. In addition, the imaging system can be widely applied to an equipment which utilizes object recognition, such as an intelligent transportation system (ITS), without being limited to moving bodies. The scope of the equipment as used herein includes an electronic equipment, an imaging equipment, a display equipment, a medical equipment, a transportation equipment (moving body), or the like.

### Modified Embodiments

The present invention is not limited to the embodiments described above, and various modifications are possible. For example, an example in which a part of the configuration of any of the embodiments is added to another embodiment or an example in which a part of the configuration of any of the embodiments is replaced with a part of the configuration of another embodiment is also one of the embodiments of the present invention.

Further, although a stack type photoelectric conversion apparatus in which the pixel region and the peripheral circuit region are arranged in different substrates has been illustrated in the above first embodiment, the application example of the present invention is not limited to the stack type photoelectric conversion apparatus. For example, the same advantageous effect as described in the above embodiment can be realized also when the present invention is applied to a photoelectric conversion apparatus in which the pixel region and the peripheral circuit region are formed on the same substrate. The photoelectric conversion apparatus may be of a front side irradiation type or a backside irradiation type.

When a front side irradiation photoelectric conversion apparatus is configured, it is preferable to arrange an anti-reflection film made of SiN or the like above the photoelectric conversion portion PD. In such a configuration, the anti-reflection film is arranged only above the photoelectric conversion portion PD side so as not to increase the capacitance Cf between the gate electrode 134 and the impurity region 226 due to the anti-reflection film.

This anti-reflection film can also be used as the protection film that reduces plasma damage at the deposition of the insulating film 140. That is, such a configuration that covers the entire upper face and side face of the gate electrode 134 with the insulating film 138 and the anti-reflection film is possible. In such a case, the insulating film 138 covers at least the side face of the gate electrode 134 on the floating diffusion portion FD side.

Further, although the case where signal charges output by the photoelectric conversion portion PD are electrons has been described as an example in the above embodiments, signal charges output by the photoelectric conversion portion PD may be holes. In such a case, the first conductivity type described above is p-type, and the second conductivity type described above is n-type.

Further, the imaging systems illustrated in the above third and fourth embodiments are examples of imaging systems to which the photoelectric conversion apparatus of the present invention may be applied, and the imaging system to which the photoelectric conversion apparatus of the present invention can be applied is not limited to the configurations illustrated in FIG. 11, FIG. 12A, and FIG. 12B.

Note that all the embodiments described above are mere embodied examples in implementing the present invention, and the technical scope of the present invention should not be construed in a limiting sense by these embodiments. That is, the present invention can be implemented in various forms without departing from the technical concept or the primary feature thereof.

### Fifth Embodiment

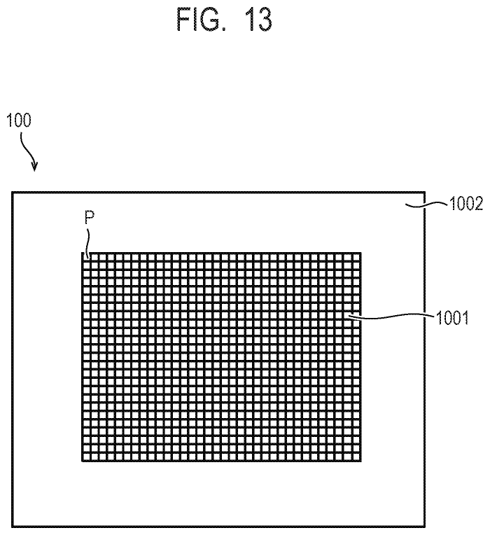

A photoelectric conversion apparatus and a manufacturing method thereof according to a fifth embodiment of the present disclosure will be described with reference to FIG. 13 to FIG. 22B.

In a photoelectric conversion apparatus including a photoelectric conversion element, there is a demand for reducing characteristic deterioration. In the conventional photoelectric conversion apparatus, however, when a photoelectric conversion element is irradiated with a significantly intense light, dark output of the pixel thereof changes before and after the light irradiation, and this may result in characteristic deterioration.

The present embodiment intends to provide a photoelectric conversion apparatus and a manufacturing method thereof that can reduce characteristic deterioration due to light irradiation.

According to the present embodiment, characteristic deterioration due to light irradiation can be reduced.

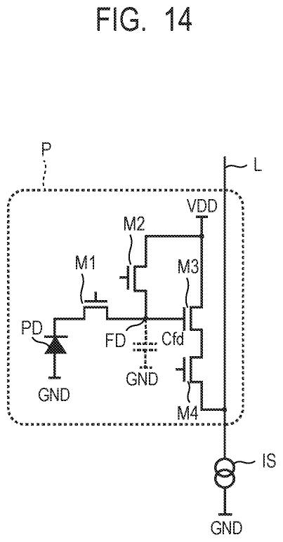

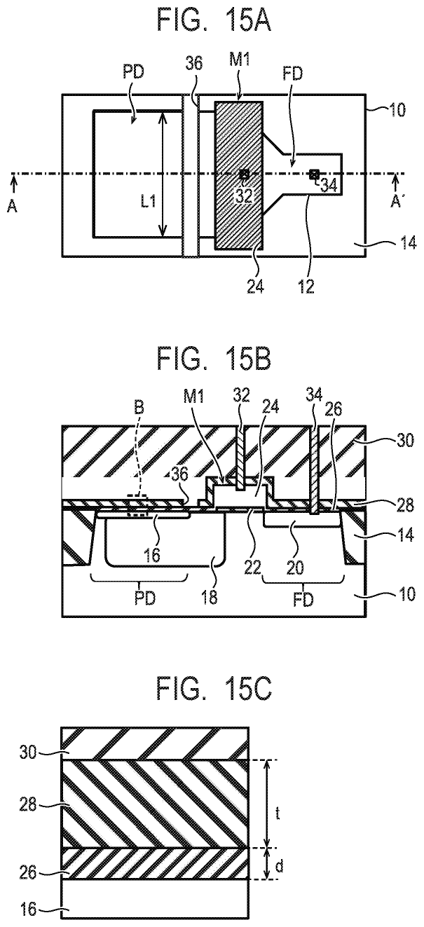

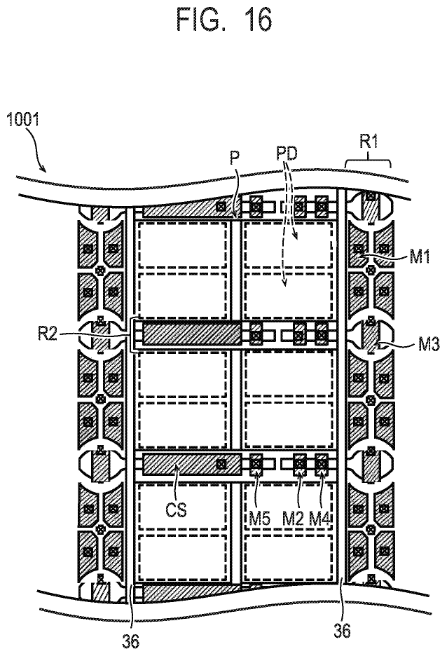

First, the structure of the photoelectric conversion apparatus according to the present embodiment will be described with reference to FIG. 13 to FIG. 16. FIG. 13 is a plan view illustrating the configuration of the photoelectric conversion apparatus according to the present embodiment. FIG. 14 is a circuit diagram illustrating a pixel in the photoelectric conversion apparatus according to the present embodiment. FIG. 15A to FIG. 15C are diagrams illustrating a part of the pixel in the photoelectric conversion apparatus according to the present embodiment. FIG. 16 is a plan view illustrating an example of a layout of pixels in the photoelectric conversion apparatus according to the present embodiment.

As illustrated in FIG. 13, the photoelectric conversion apparatus 100 according to the present embodiment is an imaging apparatus used for capturing an image and has a pixel region 1001 and a peripheral circuit region 1002. A plurality of pixels P arranged in a matrix are provided in the pixel region 1001. A circuit that performs signal processing or the like on a signal output from each pixel of the pixel region 1001 is provided in the peripheral circuit region 1002. The circuit provided in the peripheral circuit region 1002 may be, for example, a vertical scanning circuit, a readout circuit, a horizontal scanning circuit, an output circuit, a control circuit, or the like. The pixel region 1001 and the peripheral circuit region 1002 are formed on the same substrate.

Note that the arrangement of the plurality of pixels P is not limited to a matrix. For example, the arrangement of the plurality of pixels P may be one dimensional. Further, the number of pixels P included in the pixel region 1001 may be one without being limited to two or more.

As illustrated in FIG. 14, for example, each pixel P of the pixel region 1001 has a photoelectric conversion portion PD, a transfer transistor M1, a reset transistor M2, an amplifier transistor M3, and a select transistor M4. Each of the transistors M1, M2, M3, and M4 is formed of a metal oxide semiconductor (MOS) field effect transistor, for example.

The photoelectric conversion portion PD is a photodiode, for example, the anode is connected to a ground node, and the cathode is connected to the source of the transfer transistor M1. The drain of the transfer transistor M1 is connected to the source of the reset transistor M2 and the gate of the amplifier transistor M3. The connection node of the drain of the transfer transistor M1, the source of the reset transistor M2, and the gate of the amplifier transistor M3 is a so-called a floating diffusion portion FD. The floating diffusion portion FD includes a capacitance component (floating diffusion capacitance Cfd) formed of a parasitic capacitance such as a wiring capacitance, a junction capacitance, or the like and has a function as a charge holding portion. The drain of the reset transistor M2 and the drain of the amplifier transistor M3 are connected to a power source node to which a voltage VDD is supplied. The source of the amplifier transistor M3 is connected to the drain of the select transistor M4. The source of the select transistor M4 is connected to an output line L. The output line L is connected to the current source IS.

The photoelectric conversion portion PD converts (photoelectrically converts) an incident light into an amount of charges in accordance with a light amount and accumulates the generated charges. When turned on, the transfer transistor M1 transfers charges held in the photoelectric conversion portion PD to the floating diffusion portion FD. The floating diffusion portion FD has a voltage corresponding to the amount of charges transferred from the photoelectric conversion portion PD in accordance with charge-to-voltage conversion caused by the capacitance thereof. The amplifier transistor M3 is configured such that the voltage VDD is supplied to the drain and a bias current is supplied to the source from the current source IS via the select transistor M4 and forms an amplifier portion (source follower circuit) whose gate is the input node. Thereby, the amplifier transistor M3 outputs a signal based on the voltage of the floating diffusion portion FD to the output line L via the select transistor M4. When turned on, the reset transistor M2 resets the floating diffusion portion FD to a voltage in accordance with the voltage VDD.

In FIG. 15A to FIG. 15C, the photoelectric conversion portion PD, the transfer transistor M1, and the floating diffusion portion FD formed in a substrate 10 are extracted and illustrated from one pixel P arranged in the pixel region 1001 illustrated in FIG. 13. FIG. 15A is a plan view illustrating a part of the pixel P in the photoelectric conversion apparatus 100 according to the present embodiment, which is a plan view of the pixel when viewed from the upper face side that a light enters. FIG. 15B is a sectional view taken along a line A-A′ illustrated in FIG. 15A. FIG. 15C is a sectional view illustrating an enlarged rectangular region B surrounded by a dashed line illustrated in FIG. 15B.

The substrate 10 is a semiconductor substrate such as a silicon substrate, for example. An element isolation region 14 electrically isolating the regions of the substrate 10 from each other and defining an active region 12 is provided in the substrate 10. The element isolation region 14 is an insulating isolation region formed of a silicon oxide film, for example, by local oxidation of silicon (LOCOS), shallow trench isolation (STI), or the like, for example.

In the active region 12, a photodiode forming the photoelectric conversion portion PD, the transfer transistor M1, and the floating diffusion portion FD as a charge holding portion that holds charges transferred from the photoelectric conversion portion PD are arranged. The photoelectric conversion portion PD and the floating diffusion portion FD arranged in the active region 12 are isolated from each other by the element isolation region 14 between adjacent pixels P to prevent color mixture. However, the isolation between adjacent pixels P is not limited to the above. The isolation between the pixels P may be isolation by using a diffusion layer in which an impurity region is provided between the pixels P, or both isolation by using the element isolation region 14 and isolation by using the diffusion layer may be used. When the isolation by using the diffusion layer is used, an impurity region of a conductivity type that is opposite to the conductivity type of the impurity region 16 can be provided between the pixels P.

The photoelectric conversion portion PD is an embedded photodiode including the impurity region 16 of the first conductivity type provided on the surface of the active region 12 of the substrate 10 and an impurity region 18 of the second conductivity type provided in contact with the underside of the impurity region 16. The second conductivity type is a conductivity type opposite to the first conductivity type. For example, the first conductivity type is P-type, and the second conductivity type is N-type. The impurity region 16 is provided to form the photoelectric conversion portion PD in the embedded photodiode structure and has a roll of suppressing influence of a dark current occurring by influence of the interface state of the surface part of the substrate 10. The impurity region 18 is a charge accumulation layer used for accumulating signal charges by the photoelectric conversion portion PD. Note that a configuration without the impurity region 16 may be possible. Note that the substrate 10 is of the first conductivity type, or a well of the first conductivity type (not illustrated) is provided inside the active region 12.

The floating diffusion portion FD is formed of an impurity region 20 of the second conductivity type provided on the surface part of the active region 12 of the substrate 10 so as to be spaced apart from the impurity region 18.

The transfer transistor M1 includes a gate electrode 24 provided via a gate insulating film 22 on the substrate 10 between the impurity region 18 and the impurity region 20. The gate insulating film 22 is formed of an insulating film such as a silicon oxide film, for example. The gate electrode 24 is formed of a polysilicon or the like, for example.

In the photodiode forming the photoelectric conversion portion PD, photoelectric conversion is performed by a depletion layer created by p-n junction. When a light enters the photoelectric conversion portion PD, carriers that are to be signal charges are generated. The generated carriers can be transferred to the impurity region 20 forming the floating diffusion portion FD through the transfer transistor M1. The transfer transistor M1 can be switched between an on-state and an off-state by application of a voltage to a contact plug 32 described later connected to the gate electrode 24 via a wiring (not illustrated). Thereby, an accumulation period or the like of charges in the photoelectric conversion portion PD is adjusted.

Further, the impurity region 20 forming the floating diffusion portion FD is of the same conductivity type as the impurity region 18 of the photoelectric conversion portion PD and has a roll as the drain when the impurity region 18 of the photoelectric conversion portion PD is regarded as the source. Carriers transferred to the impurity region 20 are transferred to a wiring (not illustrated) or a transistor (not illustrated) via a contact plug 34 described later connected to the impurity region 20. Thereby, a signal in accordance with the number of carriers accumulated in the impurity region 20 can be read out to the peripheral circuit region 1002. Note that the impurity region 20 forming the floating diffusion portion FD may be shared by a plurality of pixels P.

A silicon oxide film 26 that is an insulating film is provided on the substrate 10 in which the impurity regions 16, 18, and 20 are provided, on the gate electrode 24, and on the side face of the gate electrode 24. Note that another insulating film may be provided instead of the silicon oxide film 26.

A silicon nitride film 28 that may function as an anti-reflection film and an etching stop film as described later is provided on the silicon oxide film 26. For example, the silicon nitride film 28 is provided over the photoelectric conversion portion PD, the transfer transistor M1, and the floating diffusion portion FD provided in the substrate 10. Note that the silicon nitride film 28 is provided on a region including at least photoelectric conversion portion PD of the substrate 10.

An interlayer insulating film 30 is provided on the silicon nitride film 28. The interlayer insulating film 30 is formed of a silicon oxide film or the like, for example. The contact plug 32 connected to the gate electrode 24 and the contact plug 34 connected to the impurity region 20 forming the floating diffusion portion FD are provided inside the silicon oxide film 26, the silicon nitride film 28, and the interlayer insulating film 30 that are stacked in this order. Each of the contact plugs 32 and 34 is formed of a conductive member made of a metal including titanium, tungsten, aluminum, copper, or the like or an alloy containing these metals, for example.

The side of the contact plug 32 connected to the gate electrode 24 is in contact with the silicon nitride film 28 provided on the gate electrode 24. Further, the side of the contact plug 34 connected to the impurity region 20 forming the floating diffusion portion FD is in contact with the silicon nitride film 28 formed above the floating diffusion portion FD.

Note that the silicon nitride film 28 forms a film provided near the surface of the substrate 10. Specifically, it is preferable that the silicon nitride film 28 be provided such that the distance d in the film thickness direction from the surface of the substrate 10, which is an interface with the silicon oxide film 26 of the substrate 10, to the silicon nitride film 28 is smaller than the film thickness t of the silicon nitride film 28. That is, it is preferable that the film thickness t of the silicon nitride film 28 be larger than the distance d. For example, the distance d is 5 to 25 nm corresponding to the film thickness of the silicon oxide film 26. For example, the film thickness t is 25 to 100 nm. Further, it is preferable that the height of the upper face of the silicon nitride film 28 be lower than the height of the gate electrode 24. The height of the gate electrode 24 from the surface of the substrate 10 to the upper face of the gate electrode 24 is 100 to 300 nm, for example.

The silicon nitride film 28 can function as an anti-reflection film that prevents reflection at the light receiving surface of the photoelectric conversion portion PD. That is, the silicon nitride film 28 is a film to reduce reflection of a light entering the photoelectric conversion portion PD occurring at the surface of the substrate 10. The silicon nitride film 28 that functions as an anti-reflection film has a refractive index between the refractive index of the interlayer insulating film 30 and the refractive index of the substrate 10.

Furthermore, the silicon nitride film 28 may function as an anti-reflection film and also may function as an etching stop film when contact holes in which the contact plugs 32 and 34 are embedded are opened in the interlayer insulating film 30. That is, the silicon nitride film 28 is a film that is less likely to be etched than the interlayer insulating film 30 in the etching to form contact holes in which the contact plugs 32 and 34 are embedded.

The silicon nitride film 28 is a film deposited by a thermal chemical vapor deposition (CVD) method using hexachlorodisilane (HCD) Si₂Cl₆ as a source gas as described later, for example. The silicon nitride film 28 deposited by using HCD as a source gas contains a certain amount of chlorine. Specifically, the chlorine concentration of the silicon nitride film 28 deposited by using HCD as a source gas is 0.5 to 5 atom %, for example.

The silicon nitride film 28 has an end portion on the photoelectric conversion portion PD side of the side face of the gate electrode 24 on the photoelectric conversion portion PD side. Thereby, a path of carries via the silicon nitride film 28 from a portion on the photoelectric conversion portion PD of the silicon nitride film 28 to the gate electrode 24 is made discontinuous. The end portion of the silicon nitride film 28 defines the opening 36. The end portion of the silicon nitride film 28 includes a part or the whole of the end face of the silicon nitride film 28 continuous to at least the upper face of the silicon nitride film 28. In this example, in the silicon nitride film 28, the opening 36 forming a discontinuous portion of the silicon nitride film 28 is provided in the region between a part above the photoelectric conversion portion PD and the gate electrode 24. The opening 36 is provided in the region of the silicon nitride film 28 on the photoelectric conversion portion PD side of the side face of the gate electrode 24 on the photoelectric conversion portion PD side. Thus, the end portion of the gate electrode 24 side of the silicon nitride film 28 located above the photoelectric conversion portion PD is located on the photoelectric conversion portion PD side of the gate electrode 24. A portion of the silicon nitride film 28 covering the photoelectric conversion portion PD is cut by the opening 36 on the photoelectric conversion portion PD side of the side face of the gate electrode 24 on the photoelectric conversion portion PD side and is discontinuous from a portion of the silicon nitride film 28 covering the gate electrode 24.

The opening 36 that makes the silicon nitride film 28 discontinuous may reach the silicon oxide film 26 that is a base layer of the silicon nitride film 28 or may be a hole or a recess where the silicon nitride film 28 partially remains at a predetermined film thickness in the bottom that is the end on the silicon oxide film 26 side. When the opening 36 reaches the silicon oxide film 26, the end face of the silicon nitride film 28 continues to the under face of the silicon nitride film 28. Note that the silicon nitride film 28 can have a discontinuous path of carriers to the gate electrode 24 by any means without being limited to the opening 36. For example, with the end portion of the silicon nitride film 28 on the gate electrode 24 side being located on the photoelectric conversion portion PD side of the gate electrode 24, the silicon nitride film 28 can have a discontinuous path of carriers to the gate electrode 24. In such a case, the silicon nitride film 28 is not required to cover the gate electrode 24. When the silicon nitride film 28 does not cover the gate electrode 24, the silicon nitride film 28 covering one photoelectric conversion portion PD may be discontinuous with the silicon nitride film 28 covering another photoelectric conversion portion PD.

The opening 36 has a thin rectangular plane shape extending in the gate width direction of the gate electrode 24 of the transfer transistor M1, for example, when viewed from a direction perpendicular to the substrate 10. Note that the plane shape of the opening 36 is not particularly limited, and various shapes may be employed.

The opening 36 may be provided so as to overlap a part or the whole of the impurity region 16 of the photoelectric conversion portion PD when viewed from a direction perpendicular to the substrate 10, for example. Further, the opening 36 may be provided so as not to overlap the impurity region 16 of the photoelectric conversion portion PD between the gate electrode 24 and the impurity region 16 of the photoelectric conversion portion PD, for example.

Note that, when the silicon nitride film 28 has a function of an anti-reflection film, reflection of light in the opening 36 increases, and this may result in a reduction of sensitivity. Thus, it is desirable that the opening 36 be provided so that a part overlapping the photoelectric conversion portion PD is further reduced or a part overlapping the photoelectric conversion portion PD is eliminated.

The interlayer insulating film 30 is filled in the opening 36. Note that a part or the whole of the opening 36 may be a void, or another insulating substance may be filled in the opening 36, for example, without being limited to the interlayer insulating film 30 being filled in the opening 36.

FIG. 16 illustrates an example of a layout of the pixels P in the pixel region 1001. FIG. 16 illustrates a configuration in which, in addition to the configuration of the pixel P illustrated in FIG. 14, a capacitor portion CS that functions as a holding capacitor used for accumulating charges overflown from the photoelectric conversion portion PD is connected to the floating diffusion portion FD via the switch transistor M5. The capacitor portion CS is formed of a MOS capacitor, for example. The switch transistor M5 is formed of a MOS field effect transistor, for example. The switch transistor M5 functions as a switch that controls a connection between the floating diffusion portion FD and the capacitor portion CS. Note that various layouts may be employed for the pixels P in addition to the layout illustrated in FIG. 16.

As illustrated in FIG. 16, the photoelectric conversion portions PD of the pixels P are arranged in a matrix over a plurality of rows and a plurality of columns in the pixel region 1001. In a region R1, the transfer transistors M1 and the amplifier transistors M3 are provided along a column of the photoelectric conversion portions PD. The transfer transistors M1 and the amplifier transistors M3 are arranged such that respective gate width directions are along a column of the photoelectric conversion portions PD. The transfer transistors M1 are arranged in a column in association with the photoelectric conversion portions PD. Further, regions R2 are provided on every two rows between the rows of the photoelectric conversion portions PD. In the region R2, the capacitor portion CS, the switch transistor M5, the reset transistor M2, and the select transistor M4 are provided along a row of the photoelectric conversion portions PD. The switch transistor M5, the reset transistor M2, and the select transistor M4 are arranged such that respective gate longitudinal directions are along a row of the photoelectric conversion portions PD.

Each of the openings 36 provided in the silicon nitride film 28 is arranged on a column of the photoelectric conversion portions PD side of the region R1 in which the transfer transistors M1 and the like are provided, that is, on the photoelectric conversion portion PD side of the side face of the gate electrode of the transistor M1 on the photoelectric conversion portion PD side. The opening 36 is continuously formed in a belt shape along the plurality of photoelectric conversion portions PD on a column of the photoelectric conversion portions PD. Note that a plurality of openings 36 separated from each other may be arranged with respect to a plurality of photoelectric conversion portions PD on a column of the photoelectric conversion portions PD.

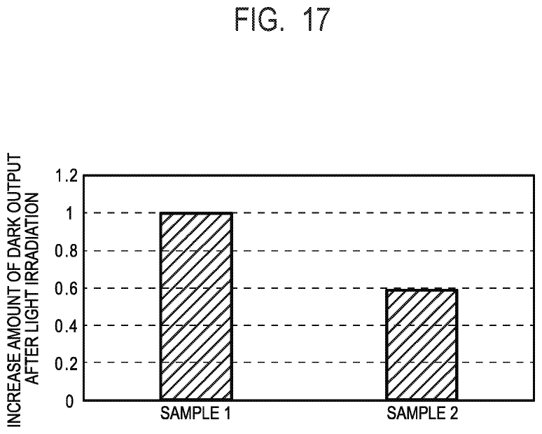

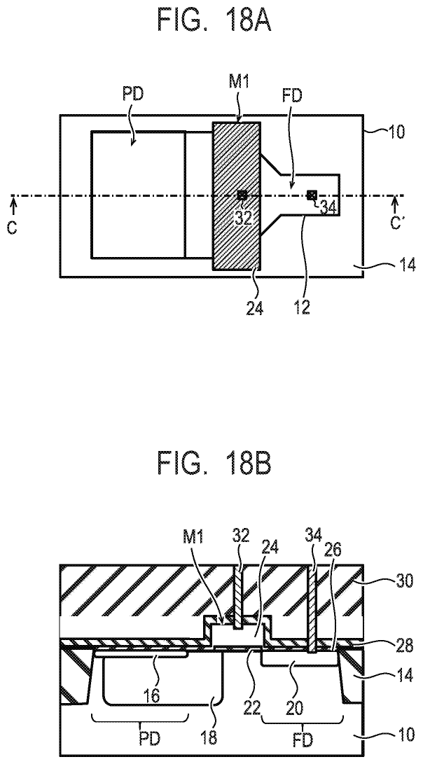

In the photoelectric conversion apparatus 100 according to the present embodiment, in the silicon nitride film 28 formed above the photoelectric conversion portion PD and the gate electrode 24, the opening 36 is provided on the photoelectric conversion portion PD side of the side face of the gate electrode 24. Thereby, the silicon nitride film 28 is made discontinuous by the opening 36 on the photoelectric conversion portion PD side of the side face of the gate electrode 24. With the silicon nitride film 28 being discontinuous in such a way, an increase in dark output of the pixel P occurring after the photoelectric conversion portion PD is irradiated with light is reduced, and characteristic deterioration due to light irradiation to the photoelectric conversion portion PD is therefore reduced in the photoelectric conversion apparatus 100 according to the present embodiment. This feature will be further described below with reference to FIG. 17, FIG. 18A, and FIG. 18B.

FIG. 17 is a graph illustrating a result of measuring a difference (increase amount) between dark output before light irradiation and dark output after light irradiation after irradiating samples 1 and 2 of a photoelectric conversion apparatus with light for one hour, respectively. The sample 1 is a sample of a photoelectric conversion apparatus according to a comparative example illustrated in FIG. 18A and FIG. 18B. The sample 2 is a sample of the photoelectric conversion apparatus 100 according to the present embodiment. Note that FIG. 17 illustrates the difference of dark output measured for the sample 2, where the difference of dark output measured for the sample 1 is defined as 1.

FIG. 18A is a plan view illustrating a part of a pixel in the photoelectric conversion apparatus according to the comparative example, which is a plan view when the pixel is viewed from the upper face side that a light enters. FIG. 18B is a sectional view taken along a line C-C′ illustrated in FIG. 18A. Except for a feature that the opening 36 is not provided in the silicon nitride film 28, the photoelectric conversion apparatus according to the comparative example illustrated in FIG. 18A and FIG. 18B has substantially the same configuration as the photoelectric conversion apparatus 100 according to the present embodiment illustrated in FIG. 15A to FIG. 15C or the like including an unillustrated portion.

As illustrated in FIG. 17, while dark output increases after light irradiation with respect to samples 1 and 2, respectively, an increase amount of dark output in the sample 2 is reduced compared to the sample 1. The increase amount of dark output of the sample 2 is around 60% of the increase amount of dark output of the sample 1.

When a photoelectric conversion apparatus is irradiated with a light, in particular when irradiated with an intense light, this may generate carriers optically excited by a defect or the like present in the silicon nitride film 28 above the photoelectric conversion portion PD that the light enters. The carriers generated in such a way are attracted to a part near the gate electrode 24 when a voltage is applied to the gate electrode 24 that is a transfer gate, and an electric field is applied to the substrate interface. Charges may be trapped therein, or a dark current may occur, which may contribute to variation of output from the photoelectric conversion portion PD. In particular, in a case of the silicon nitride film 28 deposited by a thermal CVD method using HCD as a source gas, carriers which may contribute to output variation are likely to occur. As described above, when the silicon nitride film 28 is a film provided near the surface of the substrate 10, output from the photoelectric conversion portion PD may significantly vary. The opening 36 can block a transfer path of such carriers toward the gate electrode 24 and reduce a retention region of the carriers. Thus, it is considered that, in the photoelectric conversion apparatus 100 according to the present embodiment, the increase of dark output occurring after light irradiation was reduced and characteristic deterioration was therefore reduced.

Herein, the opening 36 may be provided with a shorter length than the length L1 of the photoelectric conversion portion PD in the gate width direction of the gate electrode 24 of the transfer transistor M1, may be provided with the same length as the length L1, or may be provided with a longer length than the length L1. However, the opening 36 longer than the length L1 enhances the effect of blocking the transfer path of carriers. It is therefore preferable that the opening 36 be provided with a length that is longer than the length L1 of the photoelectric conversion portion PD in the gate width direction of the gate electrode 24.

Further, as described above, a part or the whole of the opening 36 may be a void, or a part of the whole of the opening 36 may be filled with an insulating substance. When the insulating substance filled in the opening 36 is a substance having a higher insulating property than the silicon nitride film 28, that is, a substance having a higher resistance than the silicon nitride film 28, transfer of carriers can be more reduced. It is therefore preferable that the insulating substance filled in the opening 36 be a substance having a higher resistance than the silicon nitride film 28.

Further, it is preferable that the opening 36 be opened with a width by which a sufficient insulating effect is obtained in the gate length direction of the gate electrode 24 of the transfer transistor M1, for example, a width of 50 nm or larger.

As described above, in the photoelectric conversion apparatus 100 according to the present embodiment, the opening 36 is provided in a region that is in the silicon nitride film 28 above the photoelectric conversion portion PD and is on the photoelectric conversion portion PD side of the side face of the gate electrode 24 on the photoelectric conversion portion PD. Thus, according to the photoelectric conversion apparatus 100 of the present embodiment, characteristic deterioration due to light irradiation can be reduced.

The photoelectric conversion apparatus 100 according to the present embodiment can be accommodated in a package, for example, to build an imaging system such as a camera or an information terminal embedding the package. The imaging system will be described in seventh and eighth embodiments.

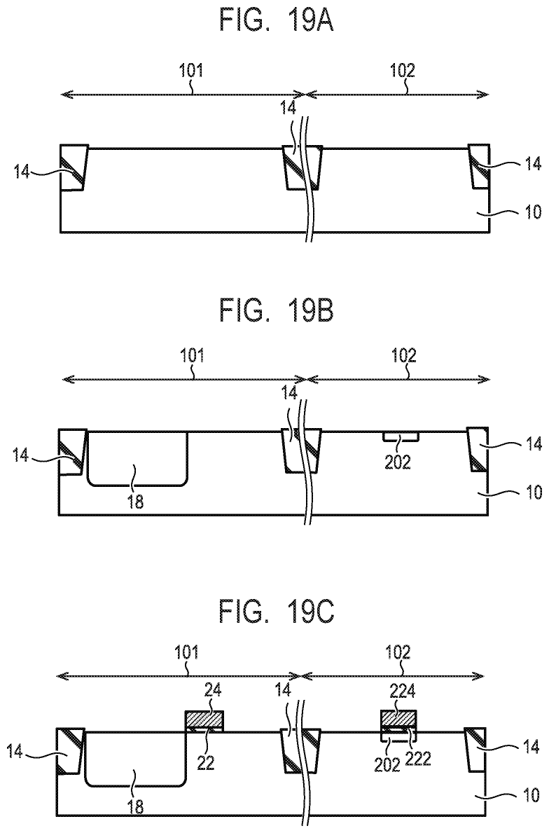

Next, a manufacturing method of the photoelectric conversion apparatus 100 according to the present embodiment will be described with reference to FIG. 19A to FIG. 22B. FIG. 19A to FIG. 22B are sectional views illustrating the manufacturing method of the photoelectric conversion apparatus 100 according to the present embodiment. In each drawing of FIG. 19A to FIG. 22B, a region 101 indicates a process cross section corresponding to the cross section illustrated in FIG. 15B, and a region 102 indicates a process cross section corresponding to the cross section of one transistor in the peripheral circuit region 1002 illustrated in FIG. 13. In the following, a transistor in the peripheral circuit region 1002 is referred to as a peripheral transistor as appropriate.

First, a trench is formed in the substrate 10 that is a semiconductor substrate such as a silicon substrate. Next, the element isolation region 14 is formed by filling an insulating member such as a silicon oxide in the trench (FIG. 19A).

Next, the impurity region 18 and the impurity region 202 in which impurities are introduced are formed in the substrate 10 (FIG. 19B). The impurity region 18 is a charge accumulation layer of the photoelectric conversion portion PD. The impurity region 202 corresponds to a channel portion of the peripheral transistor. The impurity region 18 and the impurity region 202 can be formed by introducing impurities in the substrate 10 at predetermined depths and impurity concentrations, respectively, by using a method such as ion implantation in which a resist patterned by photolithography or the like is used as a mask, for example.

Next, the gate insulating film 22 is formed on the surface of the substrate 10 of the pixel region 1001, and a gate insulating film 222 is formed on the surface of the substrate 10 of the peripheral circuit region 1002 by using a thermal oxidation method, a CVD method, or the like, for example.

Next, after a conductive film such as a poly-crystal silicon film or the like is deposited by using a CVD method, for example, this conductive film and the gate insulating films 22 and 222 are patterned to form the gate electrodes 24 and 224 (FIG. 19C). For example, photolithography and dry etching can be used for patterning a conductive film or the like. The gate electrode 24 is a gate electrode of the transfer transistor M1. The gate electrode 224 is the gate electrode of the peripheral transistor.

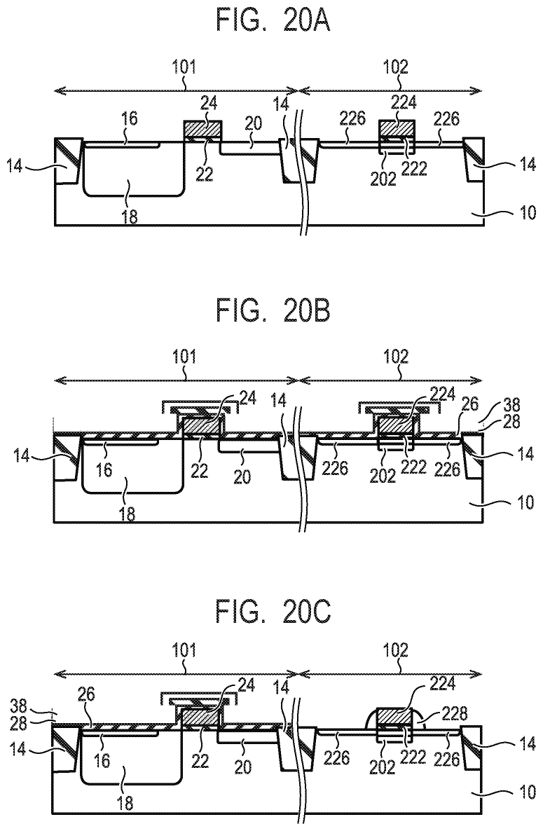

Next, the impurity region 16, the impurity region 20, and an impurity region 226 in which impurities are introduced are formed inside the substrate 10 (FIG. 20A). In the impurity region 16, the photoelectric conversion portion PD is the embedded photodiode structure. The impurity region 20 forms the floating diffusion portion FD. The impurity region 226 may function as a lightly doped drain (LDD) of the peripheral transistor. These impurity regions can be formed by introducing impurities in the substrate 10 at predetermined depths and impurity concentrations, respectively, by using a method such as ion implantation. When ion implantation is performed, while a resist patterned by a method such as photolithography can be used as a shadow mask, the gate electrode 24 or the gate electrode 224 can be used as a part of a shadow mask. In such a case, since the distance from the gate electrode 24 or the gate electrode 224 can be matched by using another pixel or another transistor, variation in pixel characteristics or transistor characteristics can be reduced.

Next, the silicon oxide film 26, the silicon nitride film 28, and the silicon oxide film 38 are sequentially deposited on the substrate 10 (FIG. 20B). The silicon oxide film 26, the silicon nitride film 28, and the silicon oxide film 38 can be deposited by using a CVD method, for example. The silicon oxide film 26 and the silicon oxide film 38 can be deposited by using a low pressure CVD (LPCVD) method that is a thermal CVD method including a process gas such as tetraethoxysilane (TEOS) or the like, for example. The growth temperature (substrate temperature) during deposition thereof can be set to range from 500 degrees Celsius to 800 degrees Celsius, for example. Further, the silicon nitride film 28 can be deposited by using a LPCVD method that is a thermal CVD method using conditions such as the growth temperature of 500 degrees Celsius to 800 degrees Celsius, a use of ammonia and HCD as a process gas, a pressure of 20 Pa to 200 Pa, or the like, for example.

Next, a sidewall 228 of the peripheral transistor or the like is formed (FIG. 20C). For example, the sidewall 228 formed of three types of films, namely, the silicon oxide film 26, the silicon nitride film 28, and the silicon oxide film 38 can be formed by etching back only a predetermined portion of the peripheral circuit region 1002. Further, the sidewall 228 can be formed by, after once removing the whole or a part of the silicon oxide film 26, the silicon nitride film 28, and the silicon oxide film 38 of the peripheral circuit region 1002 by a scheme of wet etching or the like, separately depositing an insulating film and then performing etching back thereon.

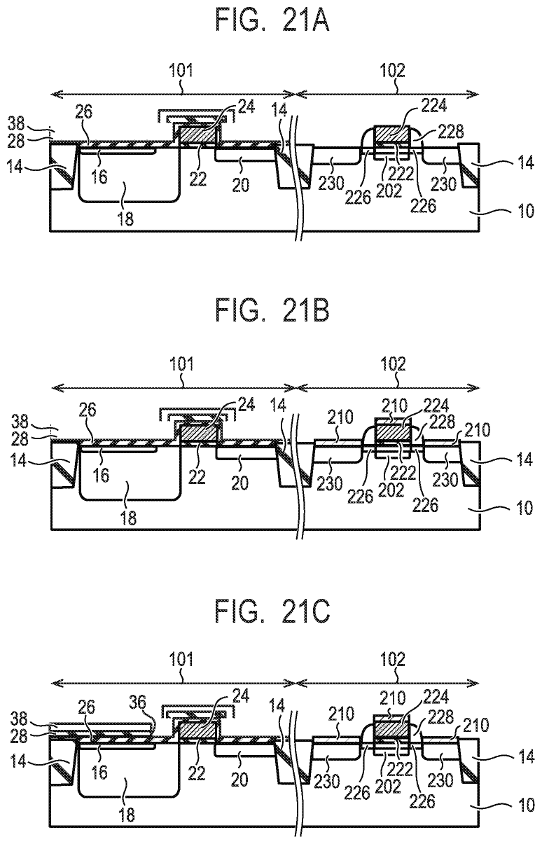

Next, an impurity region 230 in which an impurity is introduced is formed in the substrate 10 (FIG. 21A). The impurity region 230 may function as the source and the drain of the peripheral transistor. The impurity region 230 can also be formed by introducing an impurity in the substrate 10 at a predetermined depth and impurity concentration. When ion implantation is performed, while a resist patterned by a method of photolithography or the like can be used as a shadow mask, the gate electrode 224 or the sidewall 228 can be used as a part of a shadow mask.

Next, a silicide 210 is formed in an active region on the substrate 10 including the upper face of the gate electrode 224 and the upper face of the impurity region 226 (FIG. 21B). The silicide 210 is a cobalt silicide or a nickel silicide, for example. When the silicide 210 is formed, an active region that is not covered with an insulating member such as an oxide film can be silicided by depositing and annealing a metal such as cobalt, nickel, or the like, for example. After completion of silicidation, an excessive metal is removed by wet etching or the like. Silicidation of an active region can reduce a resistance.

Next, the opening 36 is patterned and formed in the silicon nitride film 28 and the silicon oxide film 38 (FIG. 21C). For example, photolithography and dry etching can be used for patterning the opening 36. By forming the opening 36 in the silicon nitride film 28 in such a way, the silicon nitride film 28 becomes discontinuous on the photoelectric conversion portion PD side of the side face of the gate electrode 24 on the photoelectric conversion portion PD side. It is preferable to form the opening 36 after silicidation of the active region in which the silicide 210 is to be formed. This is because a diffused metal may enter the photoelectric conversion portion PD and increase dark output if the opening 36 is already formed before the silicide 210 is formed.

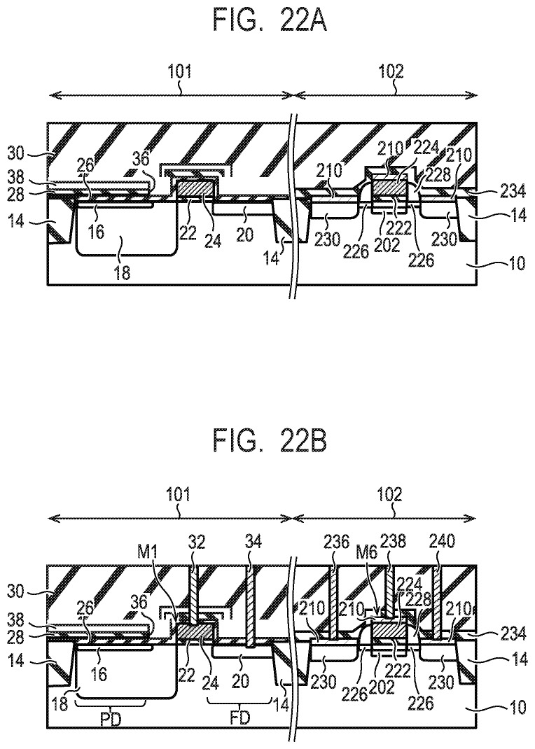

Next, after a silicon nitride film 234 is formed on the whole surface, the silicon nitride film 234 in the pixel region 1001 is removed by patterning the silicon nitride film 234. The silicon nitride film 234 can be deposited by an LPCVD method or the like. Next, the interlayer insulating film 30 is formed on the whole surface (FIG. 22A). As the interlayer insulating film 30, an insulating member such as a silicon oxide film is formed by a high density plasma (HDP) CVD method, an LPCVD method, or the like, for example. The opening 36 is filled with the interlayer insulating film 30. To fill the opening 36 without a gap, the HDPCVD method is superior to the LPCVD method.

Next, the contact plugs 32 and 34 are formed inside the interlayer insulating film 30, the silicon nitride film 28, and the silicon oxide film 26 in the pixel region 1001. In addition, the contact plugs 236, 238, and 240 are formed inside the interlayer insulating film 30 and the silicon nitride film 234 in the peripheral circuit region 1002 (FIG. 22B). Note that the interlayer insulating film 30 in the pixel region 1001 includes the silicon oxide film 38. The contact plug 32 is connected to the gate electrode 24 of the transfer transistor M1. The contact plug 34 is connected to the floating diffusion portion FD. The contact plug 238 is connected to the gate electrode 224 of the peripheral transistor M6 via the silicide 210. The contact plugs 236 and 240 are connected to the source and the drain of the peripheral transistor M6 formed of the impurity regions 226 and 230 via the silicide 210. When the contact holes in which these contact plugs are embedded are formed, the silicon nitride film 28 or the silicon nitride film 234 may function as an etching stop film. That is, after the interlayer insulating film 30 is once patterned and etched by using the silicon nitride film 28 or the silicon nitride film 234 as an etching stop film, the silicon nitride film 28 and the silicon nitride film 234 can be etched with self-alignment. After the contact holes are formed, a barrier metal of titanium, titanium nitride, or the like and a conductive member of tungsten or the like are deposited and formed in the contact holes, and an unnecessary metal is removed by a method such as an etching back method, a chemical mechanical polishing (CMP) method, or the like. Thereby, the contact plugs 32, 34, 236, 238, and 240 made of a barrier metal and a conductive member formed inside the contact holes are formed.

Next, a wiring layer, a light guide, an inner lens, a color filter, a micro-lens, and the like (which are not illustrated) are formed, and thereby the photoelectric conversion apparatus 100 according to the present embodiment can be completed.

As described above, according to the present embodiment, since the opening 36 is provided in a region that is in the silicon nitride film 28 above the photoelectric conversion portion PD and is on the photoelectric conversion portion PD side of the side face of the gate electrode 24 on the photoelectric conversion portion PD side, characteristic deterioration due to light irradiation can be reduced.

### Sixth Embodiment

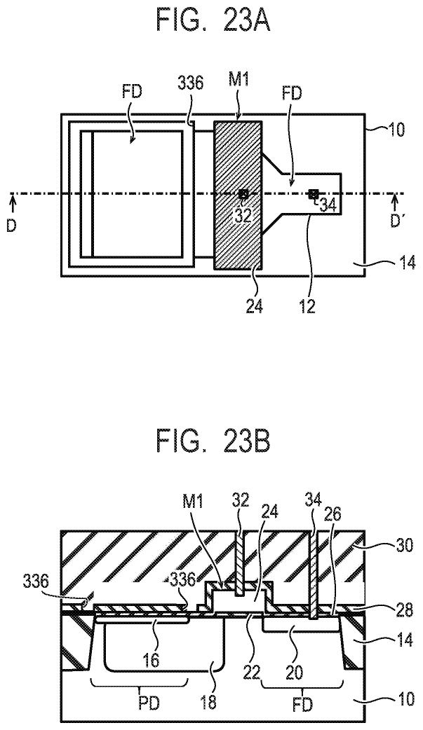

A photoelectric conversion apparatus and a manufacturing method thereof according to a sixth embodiment of the present disclosure will be described with reference to FIG. 23A and FIG. 23B. FIG. 23A and FIG. 23B are schematic diagrams illustrating a part of a pixel in the photoelectric conversion apparatus according to the present embodiment. Note that the same components as those in the photoelectric conversion apparatus and the manufacturing method thereof according to the fifth embodiment are labeled with the same references, and the description thereof will be omitted or simplified.

Although the case where the opening 36 having a rectangular plane shape when viewed from the direction perpendicular to the substrate 10 is provided in the silicon nitride film 28 has been described in the fifth embodiment, the plane shape of the opening 36 is not limited to a rectangle. In the present embodiment, a case where, instead of the opening 36 having a rectangular plane shape, an opening 336 having a frame-like plane shape surrounding the photoelectric conversion portion PD is provided in the silicon nitride film 28 will be described.

FIG. 23A is a plan view illustrating a part of the pixel P in the photoelectric conversion apparatus according to the present embodiment, which is a plan view of the pixel when viewed from the upper face side that a light enters. FIG. 23B is a sectional view taken along a line D-D′ illustrated in FIG. 23A.

In the photoelectric conversion apparatus according to the present embodiment, the opening 336 is provided in a region that is in the silicon nitride film 28 and is on the photoelectric conversion portion PD side of the side face of the gate electrode 24 so as to surround the photoelectric conversion portion PD. The opening 336 has a frame-like plane shape surrounding the photoelectric conversion portion PD when viewed from a direction perpendicular to the substrate 10. The opening 336 forms a discontinuous part in the silicon nitride film 28 in the same manner as the opening 36 according to the fifth embodiment. The silicon nitride film 28 is cut by the opening 336 to be discontinuous.

For example, the opening 336 may be provided so as to overlap a part of the photoelectric conversion portion PD when viewed from a direction perpendicular to the substrate 10 or may be provided outside the photoelectric conversion portion PD so as not to overlap the photoelectric conversion portion PD.

In the present embodiment, as described above, the opening 336 is provided in the silicon nitride film 28 so as to surround the photoelectric conversion portion PD. With such the opening 336, even when carriers occur in the silicon nitride film 28 on the photoelectric conversion portion PD when the photoelectric conversion apparatus is irradiated with light, there is no transfer path through which the carries travel to the gate electrode 24. Therefore, according to the present embodiment, an increase in dark output after light irradiation can be further reduced, and thus characteristic deterioration can be further reduced.

In the frame-like opening 336, at least a portion on the gate electrode 24 side of the transfer transistor M1 can be provided with a length in the gate width direction and a width in the gate length direction that are the same as those of the opening 36 according to the fifth embodiment.

Further, in the same manner as the opening 36 according to the fifth embodiment, a part or the whole of the opening 336 may be a void, or an insulating substance may be filled in a part or the whole of the opening 336. Note that the photoelectric conversion apparatus according to the present embodiment can be manufactured in the same manner as in the fifth embodiment.

As described above, according to the present embodiment, since the opening 336 is provided in the silicon nitride film 28 so as to surround the photoelectric conversion portion PD, characteristic deterioration due to light irradiation can be further reduced.

### Seventh Embodiment

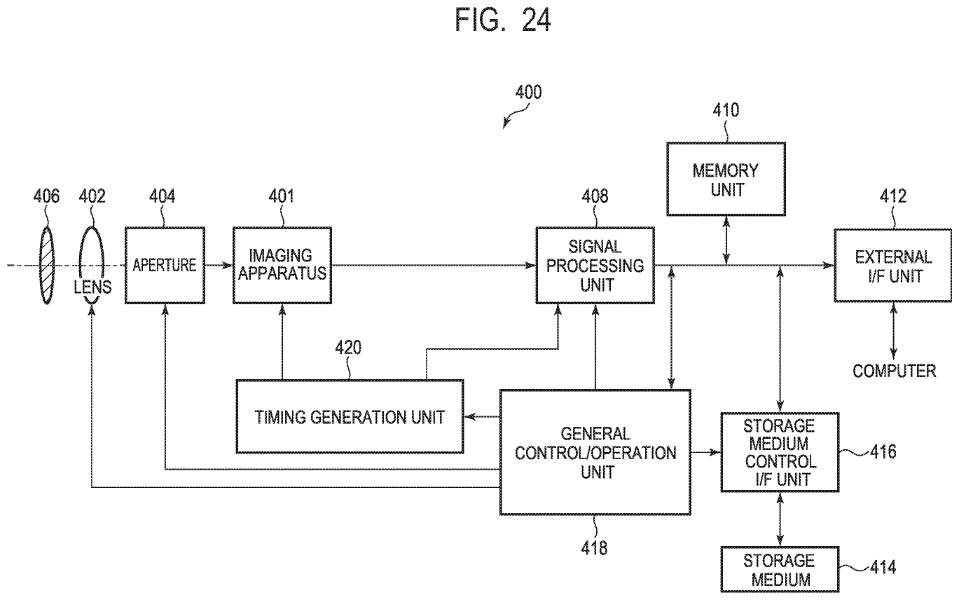

An imaging system according to a seventh embodiment of the present disclosure will be described with reference to FIG. 24. FIG. 24 is a block diagram illustrating a general configuration of the imaging system according to the present embodiment.

The photoelectric conversion apparatus 100 described in the above fifth and sixth embodiments is applicable to various imaging systems. An example of the applicable imaging system may be a digital still camera, a digital camcorder, a surveillance camera, an image reading equipment such as a copy machine or a fax machine, a mobile phone, an on-vehicle camera, an observation satellite, or the like. Further, a camera module having an optical system such as a lens and an imaging apparatus is also included in the imaging system. FIG. 24 illustrates a block diagram of a digital still camera as one example of the above.

An imaging system 400 illustrated in FIG. 24 as an example has an imaging apparatus 401, a lens 402 that captures an optical image of an object on the imaging apparatus 401, an aperture 404 that changes the amount of light passing through the lens 402, and a barrier 406 that protects the lens 402. The lens 402 and the aperture 404 are an optical system that collects light into the imaging apparatus 401. The imaging apparatus 401 is a photoelectric conversion apparatus 100 described in any of the fifth and sixth embodiments and converts an optical image captured by the lens 402 into image data.

Further, the imaging system 400 has a signal processing unit 408 that performs a process of an output signal output from the imaging apparatus 401. The signal processing unit 408 performs AD conversion to convert an analog signal output from the imaging apparatus 401 into a digital signal. Further, the signal processing unit 408 performs operations to perform various correction or compression if necessary and output image data in addition to the above. The AD conversion portion that is a part of the signal processing unit 408 may be formed on a semiconductor substrate on which the imaging apparatus 401 is provided or may be formed on a semiconductor substrate other than a substrate on which the imaging apparatus 401 is provided. Further, the imaging apparatus 401 and the signal processing unit 408 may be formed on the same semiconductor substrate.

Furthermore, the imaging system 400 has a memory unit 410 used for temporarily storing image data and an external interface unit (external OF unit) 412 used for communicating with external computer or the like. Furthermore, the imaging system 400 has a storage medium 414 such as semiconductor memory used for performing storage or readout of imaging data and a storage medium control interface unit (storage medium control I/F unit) 416 used for performing storage or readout on the storage medium 414. Note that the storage medium 414 may be built in the imaging system 400 or may be removable.

Furthermore, the imaging system 400 has a general control/operation unit 418 that controls various operations and controls the entire digital still camera and a timing generation unit 420 that outputs various timing signals to the imaging apparatus 401 and the signal processing unit 408. Here, the timing signal or the like may be externally input, and the imaging system 400 has at least the imaging apparatus 401 and the signal processing unit 408 that processes an output signal output from the imaging apparatus 401.

The imaging apparatus 401 outputs an imaging signal to the signal processing unit 408. The signal processing unit 408 implements predetermined signal processing on an imaging signal output from the imaging apparatus 401 and outputs image data. The signal processing unit 408 uses an imaging signal to generate an image.

As described above, according to the present embodiment, the imaging system to which the photoelectric conversion apparatus 100 according to each of the fifth and sixth embodiments is applied can be realized.

### Eighth Embodiment

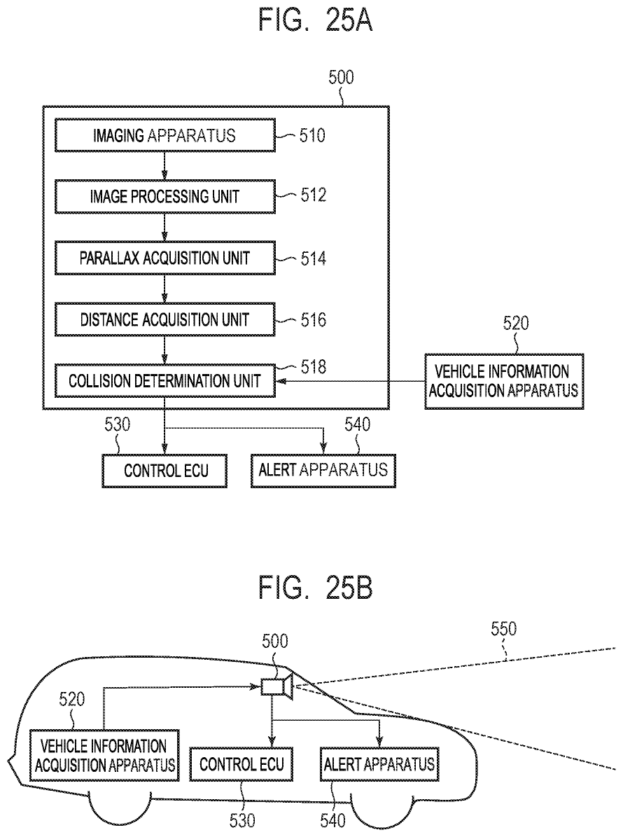

An imaging system and a moving body according to an eighth embodiment of the present disclosure will be described with reference to FIG. 25A and FIG. 25B. FIG. 25A and FIG. 25B are diagrams illustrating the configuration of the imaging system and the moving body according to the present embodiment.

FIG. 25A is a diagram illustrating an example of the imaging system regarding an on-vehicle camera. An imaging system 500 has an imaging apparatus 510. The imaging apparatus 510 is the photoelectric conversion apparatus 100 described in any of the above fifth and sixth embodiments. The imaging system 500 has an image processing unit 512 that performs image processing on a plurality of image data acquired by the imaging apparatus 510 and a parallax acquisition unit 514 that calculates a parallax (a phase difference of parallax images) from the plurality of image data acquired by the imaging system 500. Further, the imaging system 500 has a distance acquisition unit 516 that calculates a distance to the object based on the calculated parallax and a collision determination unit 518 that determines whether or not there is a collision possibility based on the calculated distance. Here, the parallax acquisition unit 514 and the distance acquisition unit 516 are an example of a distance information acquisition unit that acquires distance information on the distance to the object. That is, the distance information is information on a parallax, a defocus amount, a distance to an object, or the like. The collision determination unit 518 may use any of the distance information to determine the collision possibility. The distance information acquisition unit may be implemented by dedicatedly designed hardware or may be implemented by a software module. Further, the distance information acquisition unit may be implemented by a field programmable gate array (FPGA), an application specific integrated circuit (ASIC), or the like or may be implemented by a combination thereof.

The imaging system 500 is connected to the vehicle information acquisition apparatus 520 and can acquire vehicle information such as a vehicle speed, a yaw rate, a steering angle, or the like. Further, the imaging system 500 is connected to a control ECU 530, which is a control apparatus that outputs a control signal for causing a vehicle to generate braking force based on a determination result by the collision determination unit 518. Further, the imaging system 500 is also connected to an alert apparatus 540 that issues an alert to the driver based on a determination result by the collision determination unit 518. For example, when the collision probability is high as the determination result of the collision determination unit 518, the control ECU 530 performs vehicle control to avoid a collision or reduce damage by applying a brake, pushing back an accelerator, suppressing engine power, or the like. The alert apparatus 540 alerts a user by sounding an alert such as a sound, displaying alert information on a display of a car navigation system or the like, providing vibration to a seat belt or a steering wheel, or the like.

In the present embodiment, an area around a vehicle, for example, a front area or a rear area is captured by using the imaging system 500. FIG. 25B illustrates the imaging system when a front area of a vehicle (a capturing area 550) is captured. The vehicle information acquisition apparatus 520 transmits an instruction to the imaging system 500 or imaging apparatus 510. With such a configuration, ranging accuracy can be further improved.

Although the example of control for avoiding a collision to another vehicle has been described above, the embodiment is applicable to automatic driving control for following another vehicle, automatic driving control for not going out of a traffic lane, or the like. Furthermore, the imaging system is not limited to a vehicle such as an automobile and can be applied to a moving body (moving equipment) such as a ship, an airplane, or an industrial robot, for example. In addition, the imaging system can be widely applied to an equipment which utilizes object recognition, such as an intelligent transportation system (ITS), without being limited to moving bodies.

### Modified Embodiments

The present invention is not limited to the embodiments described above, and various modifications are possible. For example, an example in which a part of the configuration of any of the embodiments is added to another embodiment or an example in which a part of the configuration of any of the embodiments is replaced with a part of the configuration of another embodiment is also one of the embodiments of the present invention.

For example, although the case where the silicon nitride film 28 is provided over the photoelectric conversion portion PD, the transfer transistor M1, and the floating diffusion portion FD has been described as an example in the above embodiments, the present invention is not limited thereto. For example, the silicon nitride film 28 may not be provided on a part or the whole of the floating diffusion portion FD while being provided on the photoelectric conversion portion PD and the transfer transistor M1. In such a case, the contact plug 34 connected to the impurity region 20 forming the floating diffusion portion FD can be formed so as not to contact with the silicon nitride film 28.

Further, the first to fourth embodiments and the fifth to eighth embodiments may be combined. For example, both the first embodiment and the fifth embodiment may be applied to the photoelectric conversion portion PD, the floating diffusion portion FD (charge holding portion), and the transfer transistor having the gate electrode 134/24. Specifically, the configuration in which no insulating material whose relative dielectric constant is higher than or equal to 5.0 is included near the floating diffusion portion FD may be employed as with the first embodiment, and the silicon nitride film 28 on the photoelectric conversion portion PD may have the end portion (the opening 36) on the gate electrode 134/24 side as with the fifth embodiment. In such a case, the silicon nitride film is removed from the part above the floating diffusion portion FD so that the silicon nitride film deposited to form the silicon nitride film 28 does not remain above the floating diffusion potion FD. Alternatively, the insulating film 138 present above the photoelectric conversion portion PD and the floating diffusion portion FD as with the first embodiment may have the end portion or the opening 36 between a portion above the photoelectric conversion portion PD and the gate electrode 134/24 as with the fifth embodiment.

The process illustrated in FIG. 22B will be described in detail. A contact hole in which the contact plug 32 is to be arranged and a contact hole in which the contact plug 34 is to be arranged can be formed in the interlayer insulating film 30 at the same time. Before forming the contact plug 34, it is possible to ion-implant an impurity of the same conductivity type as the impurity region 20 into the impurity region 20 via the contact hole in which the contact plug 34 is to be arranged. Thereby, a resistance between the floating diffusion portion FD and the contact plug 34 can be reduced. When ion-implanting an impurity into the impurity region 20 via the contact hole in which the contact plug 34 is to be arranged, it is desirable to use a mask such as a photoresist to close the contact hole in which the contact plug 32 is to be arranged so that substantially no impurity is ion-implanted into the gate electrode 24. By filling a conductive material in the contact hole in which the contact plug 32 is to be arranged and the contact hole in which the contact plug 34 is to be arranged, it is possible to form the contact plug 32 and the contact plug 34 at the same time.

It is also possible to form the contact hole in which the contact plug 34 is to be arranged and the contact hole in which the contact plug 32 is to be arranged at respective timings in the interlayer insulating film 30. For example, the contact hole in which the contact plug 32 is to be arranged may be formed in the interlayer insulating film 30 after the contact hole in which the contact plug 34 is to be arranged is formed in the interlayer insulating film 30. In such a case, before the contact hole in which the contact plug 32 is to be arranged is formed, an impurity of the same conductivity type as the impurity region 20 may be ion-implanted into the impurity region 20 via the contact hole in which the contact plug 34 is to be arranged. Thereby, the resistance between the floating diffusion portion FD and the contact plug 34 can be reduced. At this time, since the contact hole in which the contact plug 32 is to be arranged is not formed on the gate electrode 24, substantially no impurity is ion-implanted into the gate electrode 24. By filling a conductive material in the contact hole in which the contact plug 32 is to be arranged and the contact hole in which the contact plug 34 is to be arranged, it is possible to form the contact plug 32 and the contact plug 34 at the same time. The contact hole in which the contact plug 34 is to be arranged may be formed in the interlayer insulating film 30 after the contact hole in which the contact plug 32 is to be arranged is formed in the interlayer insulating film 30.

The contact plug 142 connected to the semiconductor region 126 (the floating diffusion portion FD) described in the first to fourth embodiments can be formed in the same manner as the contact plug 34. Although description of the contact plug connected to the gate electrode 134 has been omitted in the first to fourth embodiments, the contact plug connected to the gate electrode 134 can be formed in the same manner as the contact plug 32. That is, the contact hole in which the contact plug 142 connected to the floating diffusion portion FD is to be arranged and the contact hole in which the contact plug connected to the gate electrode 134 is to be arranged can be formed at the same time or separately in the insulating film 140 that is an interlayer insulating film. Further, it is possible to ion-implant an impurity into the semiconductor region 126 via the contact hole in which the contact plug 142 connected to the floating diffusion portion FD is to be arranged so that no impurity is implanted into the gate electrode 134.

The contact hole in which the contact plug 142 is to be arranged and the contact hole in which the contact plug connected to the gate electrode 134 is to be arranged differ in the depth of the contact hole by the thickness of the gate electrode 134. Thus, if both the contact holes are formed in the insulating film 140 at the same time, this may cause excessive etching under the contact hole on the gate electrode 134 or insufficient etching under the contact hole in which the contact plug 142 is to be arranged. Accordingly, it is preferable to separately form the contact hole in which the contact plug 142 is to be arranged and the contact hole in which the contact plug connected to the gate electrode 134 is to be arranged. In particular, when both the insulating film 140 and the insulating film 138 are made of an insulating material whose primary component is silicon oxide, it is difficult to have etching selection of the insulating film 140 and the insulating film 138, and a sufficient etching stop function is not expected for the insulating film 138. The insulating material whose primary component is silicon oxide as used herein may include not only silicon oxide but also a porous insulating material such as nano-clustering silica, a low dielectric constant material such as silicon oxy carbide (SiOC), or the like. Therefore, when both the insulating film 140 and the insulating film 138 are made of an insulating material whose primary component is silicon oxide, it is preferable to separately form the contact hole in which the contact plug 142 is to be arranged and the contact hole in which the contact plug connected to the gate electrode 134 is to be arranged.

Further, the conductivity type of the impurity region illustrated in the above embodiment can be changed, and all the conductivity types may be opposite, for example. Further, the circuit configuration within the pixel illustrated in FIG. 14, the layout of the pixel illustrated in FIG. 16, and the like each are an example, which may be different from what has been illustrated.

Further, each of the photoelectric conversion apparatuses illustrated in the above embodiments can be used as an apparatus intended for acquiring an image, that is, an imaging apparatus. Further, an application example of the photoelectric conversion apparatuses illustrated in the above embodiments is not necessarily limited to an imaging apparatus and, in the application to the apparatus intended for ranging as described in the above eighth embodiment, for example, it is not necessarily required to output an image. In such a case, it can be said that the above apparatus is a photoelectric conversion apparatus that converts optical information into a predetermined electrical signal. An imaging apparatus is one of the photoelectric conversion apparatuses.

Further, the imaging systems illustrated in the above third, fourth, seventh and eighth embodiments are examples of imaging systems to which the photoelectric conversion apparatus of the present invention may be applied, and the imaging system to which the photoelectric conversion apparatus of the present invention can be applied is not limited to the configurations illustrated in FIG. 11, FIG. 12A, FIG. 12B, FIG. 24, FIG. 25A, and FIG. 25B.

Note that all the embodiments described above are mere embodied examples in implementing the present invention, and the technical scope of the present invention should not be construed in a limiting sense by these embodiments. That is, the present invention can be implemented in various forms without departing from the technical concept or the primary feature thereof.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-047077, filed Mar. 14, 2019, and Japanese Patent Application No. 2019-068300, filed Mar. 29, 2019, which are hereby incorporated by reference herein in their entirety.

What is claimed is:

1. A photoelectric conversion apparatus comprising:
a substrate having a photoelectric conversion portion and a floating diffusion portion;
a gate electrode of a transfer transistor provided on the substrate and configured to transfer charges generated by the photoelectric conversion portion to the floating diffusion portion;
a first film formed of an insulating material whose relative dielectric constant is lower than 5.0 and provided so as to cover at least a side face of the gate electrode of the transfer transistor, the side face being on the floating diffusion portion side;
a second film provided on the first film; and
a contact plug being in contact with the second film and connected to the transfer transistor,
wherein in a range which is above the floating diffusion portion and in which a distance from an intersection line of a face including the side face of the gate electrode and a surface of the substrate is less than or equal to a distance corresponding to a height of the gate electrode from the surface, the photoelectric conversion apparatus includes no insulating material whose relative dielectric constant is higher than or equal to 5.0.

2. The photoelectric conversion apparatus according to claim 1, wherein in a range which is above the floating diffusion portion and from the surface to a height of an upper face of the gate electrode and in which a distance from the side face of the gate electrode is less than or equal to a distance corresponding to the height of the gate electrode from the surface, the photoelectric conversion apparatus includes no insulating material whose relative dielectric constant is higher than or equal to 5.0.

3. The photoelectric conversion apparatus according to claim 1, wherein in a range which is above the floating diffusion portion and from the surface to a height of an upper face of the gate electrode, the photoelectric conversion apparatus includes no insulating material whose relative dielectric constant is higher than or equal to 5.0.

4. The photoelectric conversion apparatus according to claim 1, wherein in a range which is above the floating diffusion portion and from the surface to a height that is twice a height of an upper face of the gate electrode, the photoelectric conversion apparatus includes no insulating material whose relative dielectric constant is higher than or equal to 5.0.

5. The photoelectric conversion apparatus according to claim 1, wherein the first film is formed of an insulating material whose nitrogen concentration is less than 10 atm %.

6. The photoelectric conversion apparatus according to claim 1, wherein the first film includes at least one of silicon oxide, silicon oxy carbide, and a porous insulating material.

7. The photoelectric conversion apparatus according to claim 1, wherein a dielectric constant of the first film is lower than a dielectric constant of the second film.

8. The photoelectric conversion apparatus according to claim 1, wherein the second film is formed of silicon oxide.

9. The photoelectric conversion apparatus according to claim 1, wherein an argon concentration of the second film is higher than an argon concentration of the first film.

10. The photoelectric conversion apparatus according to claim 1, wherein a film thickness of the first film is thinner than a thickness corresponding to a height of the gate electrode.

11. The photoelectric conversion apparatus according to claim 1, wherein the second film is at least partially located at a position closer to the substrate than an upper face of the gate electrode.

12. The photoelectric conversion apparatus according to claim 1,
wherein the first film has an opening in a region except a region in which the gate electrode is provided, and
wherein the second film is provided inside the opening.

13. The photoelectric conversion apparatus according to claim 1, wherein a gate insulating film of the transfer transistor is formed of an insulating material containing nitrogen.

14. The photoelectric conversion apparatus according to claim 13, wherein the gate insulating film of the transfer transistor extends between the floating diffusion portion and the first film.

15. The photoelectric conversion apparatus according to claim 1,
wherein a pixel including the photoelectric conversion portion, the floating diffusion portion, and the transfer transistor is provided on a first face side of the substrate, and
wherein a light entering a second face side opposed to the first face of the substrate enters the photoelectric conversion portion.

16. The photoelectric conversion apparatus according to claim 1,
wherein a pixel region including a plurality of pixels is provided on the substrate,
the photoelectric conversion apparatus further comprising a semiconductor substrate stacked on the substrate,
wherein at least a part of a peripheral circuit that controls readout of a signal from the pixel region is provided in the semiconductor substrate.

17. The photoelectric conversion apparatus according to claim 1 further comprising a third film that is provided so as to cover at least the photoelectric conversion portion and suppresses reflection of an incident light at the surface of the substrate.

18. The photoelectric conversion apparatus according to claim 1, wherein the photoelectric conversion apparatus includes an insulating material whose relative dielectric constant is higher than or equal to 5.0 at a position that is distant from the surface by a length that is twice or more a height of an upper face of the gate electrode from the surface.

19. An equipment comprising:
the photoelectric conversion apparatus according to claim 1; and
a signal processing apparatus that processes a signal output from the photoelectric conversion apparatus.

20. A moving body comprising:
the photoelectric conversion apparatus according to claim 1;
an information acquisition unit that acquires information based on a signal from the photoelectric conversion apparatus; and
a control unit that controls the moving body based on the information.

21. A photoelectric conversion apparatus comprising:
a substrate having a photoelectric conversion portion;
a gate electrode of a transfer transistor provided on the substrate and configured to transfer charges generated by the photoelectric conversion portion;
a first film having a part provided above the photoelectric conversion portion;
a second film provided on the first film; and
a contact plug being in contact with the second film and connected to the transfer transistor,
wherein the part of the first film is located between the second film and the photoelectric conversion portion,
wherein the first film has an end portion between the part of the first film and a side face of the gate electrode on the photoelectric conversion side, and
wherein a portion of the second film is located between the end portion and the gate electrode.

22. The photoelectric conversion apparatus according to claim 21, wherein a distance from a surface of the substrate to the first film is smaller than a film thickness of the first film.

23. The photoelectric conversion apparatus according to claim 21, wherein the first film is a silicon nitride film, and an opening that makes the first film discontinuous in a region on the photoelectric conversion portion side of a side face of the gate electrode on the photoelectric conversion portion side is provided in the first film.

24. The photoelectric conversion apparatus according to claim 23, wherein the opening is provided with a length that is longer than a length of the photoelectric conversion portion in a gate width direction of the gate electrode.

25. The photoelectric conversion apparatus according to claim 23, wherein the opening is provided with a width that is greater than or equal to 50 nm in a gate length direction of the gate electrode.

26. The photoelectric conversion apparatus according to claim 23, wherein a portion of the second film is filled in the opening.

27. The photoelectric conversion apparatus according to claim 21, wherein the second film is made of a substance having a higher resistance than the first film.

28. The photoelectric conversion apparatus according to claim 23, wherein the opening is provided so as to overlap at least a part of the photoelectric conversion portion when viewed from a direction perpendicular to the substrate.

29. The photoelectric conversion apparatus according to claim 23, wherein the opening is provided so as to surround the part of the first film.

30. The photoelectric conversion apparatus according to claim 21, wherein the first film is further provided on the gate electrode.

31. The photoelectric conversion apparatus according to claim 30, wherein the contact plug is in contact with the first film.

32. The photoelectric conversion apparatus according to claim 21,
wherein the substrate has a charge holding portion,
wherein charges generated by the photoelectric conversion portion are transferred to the charge holding portion by the transfer transistor, and
wherein the contact plug is a first contact plug connected to the gate electrode,
the photoelectric conversion apparatus further comprising a second contact plug connected to the charge holding portion,
wherein the first film is further provided above the charge holding portion, and
wherein the second contact plug is in contact with the first film.

33. The photoelectric conversion apparatus according to claim 21, wherein a chlorine concentration of the first film is 0.5 to 5 atm %.

34. A manufacturing method of a photoelectric conversion apparatus, the manufacturing method comprising steps of:
forming a silicon nitride film on a region on a substrate including a photoelectric conversion portion, and a transfer transistor that includes a gate electrode and transfers charges generated by the photoelectric conversion portion, wherein the region includes at least a photoelectric conversion portion; and
making the silicon nitride film discontinuous on the photoelectric conversion portion side of a side face of the gate electrode on the photoelectric conversion portion side.

35. The manufacturing method of the photoelectric conversion apparatus according to claim 34, wherein in the making the silicon nitride film discontinuous, an opening is formed in a region of the silicon nitride film, and the region is on the photoelectric conversion portion side of a side face of the gate electrode on the photoelectric conversion portion side.

36. The manufacturing method of the photoelectric conversion apparatus according to claim 34 further comprising steps of:
forming an interlayer insulating film on the silicon nitride film; and
etching the interlayer insulating film by using the silicon nitride film as an etching stop film.

37. The manufacturing method of the photoelectric conversion apparatus according to claim 34 further comprising a step of: siliciding an active region on the substrate before the step of making the silicon nitride film discontinuous.

38. An imaging system comprising:
the photoelectric conversion apparatus according to claim 21; and
a signal processing portion that processes a signal output from the photoelectric conversion apparatus.

39. A moving body comprising:
the photoelectric conversion apparatus according to claim 21;
an information acquisition unit that acquires information based on a signal from the photoelectric conversion apparatus; and
a control unit that controls the moving body based on the information.
